(19) United States
(12) Patent Application Publication
(10) Pub. No.: US 2017/0012201 A1
(43) Pub. Date: Jan. 12, 2017

(54) VAPOR DEPOSITION APPARATUS, VAPOR DEPOSITION METHOD, AND METHOD FOR PRODUCING ORGANIC ELECTROLUMINESCENT ELEMENT

(71) Applicant: SHARP KABUSHIKI KAISHA, Sakai City (JP)

(72) Inventors: Takashi OCHI, Sakai City (JP); Satoshi INOUE, Sakai City (JP); Yuhki KOBAYASHI, Sakai City (JP); Kazuki MATSUNAGA, Sakai City (JP); Shinichi KAWATO, Sakai City (JP); Katsuhiro KIKUCHI, Sakai City (JP); Masahiro ICHIHARA, Mitsuke-shi (JP); Eiichi MATSUMOTO, Mitsuke-shi (JP)

(73) Assignee: SHARP KABUSHIKI KAISHA, Sakai City (JP)

(21) Appl. No.: 15/114,316

(22) PCT Filed: Nov. 28, 2014
(86) PCT No.: PCT/JP2014/081542

§ 371 Date: Jul. 26, 2016

(30) Foreign Application Priority Data
Jan. 29, 2014 (JP) 2014-014278

(51) Int. Cl. H01L 51/00; C23C 16/455; H01L 51/56; C23C 16/50

(52) U.S. Cl. CPC H01L 51/0002; C23C 16/50; C23C 16/455; H01L 51/56; H01L 51/5012

(57) ABSTRACT

The present invention provides a vapor deposition apparatus, a vapor deposition method, and a method for producing an organic electroluminescent element which can control the vapor deposition rate on the substrate in the entire vapor deposition region with excellent precision. The vapor deposition apparatus of the present invention that forms a film on a substrate includes a first thickness monitor; and a vapor deposition unit including a vapor deposition source, the apparatus being configured to perform vapor deposition while controlling the distance between a portion of the vapor deposition source designed to eject a vaporized material and a surface of the substrate on which the vapor deposition is performed, based on a measurement result from the first thickness monitor.

### CROSS-REFERENCE TO RELATED APPLICATIONS

This application is a National Phase filing under 35 USC 371 application of International Application No. PCT/JP2014/081542, filed on Nov. 28, 2014, which claims priority to Japanese Application No. 2014-014278, filed on Jan. 29, 2014, each of which is hereby incorporated by reference in the present disclosure in their entirety.

### FIELD OF THE INVENTION

The present invention relates to vapor deposition apparatuses, vapor deposition methods, and methods for producing an organic electroluminescent element (hereinafter, also referred to as an organic EL element). More specifically, the present invention relates to a vapor deposition apparatus, a vapor deposition method, and a method for producing an organic EL element which are suitable for production of an organic EL element used on a large-sized substrate.

### BACKGROUND OF THE INVENTION

Organic electroluminescent display devices (hereinafter, also referred to as organic EL displays) employing organic EL elements as luminescent elements have drawn attention as flat display devices. These organic EL displays are self-luminous flat panel displays which do not require a backlight, and have an advantage that a wide-viewing angle display specific to self-luminous displays can be obtained. Also, since only the necessary pixels may be turned on, such organic EL displays are advantageous compared to backlight displays such as liquid crystal displays in terms of power consumption, and the organic EL displays are considered to exhibit sufficient response performance for a high-definition rapid video signals which are expected to be made into practice in the future.

Organic EL elements as used in such an organic EL display usually has a structure in which an organic material is sandwiched between electrodes (anode and cathode) from the top and bottom. Holes are injected from the anode and electrons are injected from the cathode into an organic layer made of an organic material, so that the organic layer emits light when the holes and the electrons are recombined in the organic layer. At this time, the organic EL element exhibits a luminance of hundreds to tens of thousands of candelas per square meter (cd/m²) at a drive voltage of 10 V or lower. Also, appropriately selecting the organic material, such as a fluorescent material, enables emission of light of the desired color. For these reasons, organic EL elements are very promising luminescent elements to form a multi-color or full-color display device.

Organic materials for forming an organic layer in an organic EL element commonly have low water resistance and are not suitable for a wet process. Hence, in formation of an organic layer, vacuum vapor deposition utilizing a technique of forming a thin film in vacuum is common. Therefore, in production of an organic EL element including a step of forming an organic layer, a vapor deposition apparatus provided with a vapor deposition source in a vacuum chamber has been widely used.

For example, Patent Literature 1 discloses an apparatus for producing an organic EL display capable of stably controlling the film thickness with excellent response performance. The apparatus disclosed is a film formation apparatus which detects the vapor deposition rate based on a film thickness obtained from a thickness monitor while a material is scattered from a vapor deposition source to a substrate being transferred by a substrate transfer device, predicts the thickness of a film to be formed on the substrate by vapor deposition, and controls the position of a limiting component using a control device to adjust the scattering range of the material.

### CITATION LIST

Patent Literature 1: JP 2004-225058 A

### SUMMARY OF THE INVENTION

Examples of the vapor deposition apparatus include a point source vapor deposition apparatus that performs vapor deposition while rotating the substrate using a vapor deposition source, and a scanning vapor deposition apparatus that performs vapor deposition while moving a substrate in one certain direction relatively to a vapor deposition source.

A point source vapor deposition apparatus can control the thickness of a vapor deposition film by adjusting the vapor deposition time through opening and closing of a shutter. In contrast, a scanning vapor deposition apparatus performs vapor deposition while transferring at least one of the substrate and the vapor deposition source at a constant speed, which does not allow control of the thickness of a vapor deposition film by the vapor deposition time. Hence, in the case of using a scanning vapor deposition apparatus, the film thickness has generally been controlled by the vapor deposition rate (vapor deposition speed) instead of the vapor deposition time.

FIG. 23 is a schematic view illustrating the basic structure of a scanning vapor deposition apparatus of Comparative Embodiment 1.

As illustrated in FIG. 23, the scanning vapor deposition apparatus of Comparative Embodiment 1 is provided with, as a vapor deposition source 1010, a crucible 1011 containing an organic material, a heater 1013 configured to heat the crucible 1011, and a heating power supply 1014 configured to supply electrodes to the heater 1013. The heater 1013 heat the crucible 1011 to vaporize the organic material, such that an organic layer is formed on the substrate 1030 of the organic EL element which is the film formation target. Also in vapor deposition of an organic material, the vapor deposition rate is detected by a thickness monitor 1001 and the heating temperature is adjusted based on the vapor deposition rate (measured value), whereby the vapor deposition rate is controlled.

However, control of the vapor deposition rate by the heating temperature is not regarded as easy in terms of the response performance. Such control gives an unstable control system, and does not facilitate film thickness control. Generally, organic materials have poor thermal efficiency compared to other materials, and have a relatively low vapor deposition temperature for a temperature in vacuum vapor deposition. Due to these properties, the time difference is large from adjustment of the heating temperature of the heater 1013 to a change in the vapor deposition rate through transfer of the temperature change to the organic material. Also, a change in the amount of the organic material in the crucible 1011 with time has an influence of changing the time constant in the control system, eventually changing the vapor deposition rate. In order to overcome such disadvantages, the scanning vapor deposition apparatus of Comparative Embodiment 1 employs a control method called the proportional integral derivative (PID) control to predict the behavior of the vapor deposition rate on a real-time basis from the changes in the vapor deposition rate, and controls the heating temperature based on the prediction. However, it has been difficult to achieve sufficient control precision of the vapor deposition rate even by the PID control.

FIG. 24 is a graph showing the relation between the heater temperature and the vapor deposition rate in the scanning vapor deposition apparatus of Comparative Embodiment 1.

When the inventors of the present invention actually studied the data, as shown in FIG. 24, the best result of the precision in controlling the vapor deposition rate using the scanning vapor deposition apparatus of Comparative Embodiment 1 was about the desired rate ±3%. Also, in the scanning vapor deposition apparatus of Comparative Embodiment 1, a vapor deposition rate variation directly led to a film thickness variation.

FIGS. 25 and 26 are schematic views each illustrating the basic structure of the film formation apparatus described in Patent Literature 1.

As illustrated in FIGS. 25 and 26, the film formation apparatus described in Patent Literature 1 adjusts the thickness of the vapor deposition film by moving limiting plates 1172 up and down. The thickness of the vapor deposition film is determined from the formula (vapor deposition rate)×(vapor deposition time). Here, the vapor deposition rate means the thickness of a vapor deposition film formed in one second, and is represented with the unit Å/s. In a scanning vapor deposition apparatus, a substrate is transferred in an atmosphere in which vapor deposition streams are present, and the vapor deposition time is determined by the formula (scattering range)/(transfer speed). Here, the transfer speed is constant and does not change. The scattering range represents the range (distance) in which the vapor deposition streams scatter, i.e., the width of the region subjected to the vapor deposition (vapor deposition region) in the transfer direction. The scattering range increases as the limiting plates 1172 are moved down, while it decreases as the limiting plates 1172 are moved up. That is, the technical idea of Patent Literature 1 is that since the vapor deposition time can be controlled by controlling the scattering range, the change in the vapor deposition rate can be complemented by control of the scattering range.

However, although the vapor deposition rate is uniformly changed throughout the entire vapor deposition region, moving the limiting plates 1172 up and down can merely change the positions of end portions 1142 of the vapor deposition region. Therefore, problems remain in the following cases, for example.

Here, the thickness of the vapor deposition film in the center portion of the substrate is considered. When the center portion of the substrate is about to enter the vapor deposition region, the vapor deposition rate is assumed to be stable and equal to the target vapor deposition rate. In this case, the vapor deposition rate needs not to be corrected, so that the limiting plates 1172 are disposed at the reference positions. Here, when the center portion of the substrate comes into the vapor deposition region, if the vapor deposition rate begins to drop suddenly, the positions of the limiting plates 1172 are lowered to correct the vapor deposition rate, so that the scattering range is increased. However, the center portion of the substrate is already in the vapor deposition region, and thus passes through the region where the vapor deposition rate has dropped. Then, if vapor deposition rate becomes stable again when the center portion of the substrate beings to go out of the vapor deposition region, the limiting plates 1172 are returned to the reference positions. Then, the center portion of the substrate goes out of the vapor deposition region, and thereby a film is assumed to have been completed.

In the above case, even though the vapor deposition rate has dropped, the vapor deposition time for the center portion of the substrate is the same as the vapor deposition time of the case that vapor deposition was performed ideally at the target vapor deposition rate. Therefore, in the center portion of the substrate, the dropped amount of the vapor deposition rate is not corrected, so that the thickness of the resulting vapor deposition film is smaller than the target thickness.

This phenomenon can occur in the entire substrate, and therefore the changes in the vapor deposition rate cannot be uniformly corrected in the substrate plane by the adjustment of the scattering range described in Patent Literature 1. Therefore, the thickness of the vapor deposition film can be uneven in the substrate plane. That is, the problem described above can possibly be prevented if the vapor deposition rate does not change frequently, but a frequent change in the vapor deposition rate can raise this problem.

Also, as described above, a point source vapor deposition apparatus can adjust the vapor deposition time by opening and closing of a shutter, but the point source vapor deposition apparatus has the same problem as in the case of the scanning vapor deposition apparatus that the control of the vapor deposition rate is difficult. For this reason, when multiple materials are simultaneously vapor-deposited using multiple vapor deposition sources, i.e., when vapor co-deposition is performed, a vapor deposition film having the desired composition may not be formed. This is because vapor co-deposition requires control of the ratios of multiple materials with high precision.

The present invention has been made in view of such a current state of the art, and aims to provide a vapor deposition apparatus, a vapor deposition method, and a method for producing an organic electroluminescent element, which can control the vapor deposition rate on the substrate in the entire vapor deposition region with excellent precision.

One aspect of the present invention is a vapor deposition apparatus that forms a film on a substrate, including:

a first thickness monitor; and

a vapor deposition unit including a vapor deposition source,

the apparatus being configured to perform vapor deposition while controlling the distance between a portion of the vapor deposition source designed to eject a vaporized material and a surface of the substrate on which the vapor deposition is performed, based on a measurement result from the first thickness monitor.

Hereinafter, this vapor deposition apparatus is also referred to as the vapor deposition apparatus of the present invention.

Preferred embodiments of the vapor deposition apparatus of the present invention are described below. These preferred embodiments may be appropriately combined with each other. Any embodiment obtained by combining two or more of these preferred embodiments is also one preferred embodiment.

The vapor deposition apparatus of the present invention may further include a vapor deposition source moving mechanism configured to move the vapor deposition source to change the height of the portion designed to eject a vaporized material.

The vapor deposition apparatus of the present invention may control the distance by proportional control or proportional integral derivative (PID) control.

The vapor deposition source may include a heating device,

the vapor deposition apparatus of the present invention may further include a second thickness monitor, and

the vapor deposition apparatus of the present invention may be configured to perform vapor deposition while controlling the output of the heating device based on a measurement result from the second thickness monitor.

The vapor deposition apparatus of the present invention may further include a vapor deposition source moving mechanism configured to move the vapor deposition source to change the height of the portion designed to eject a vaporized material,

the second thickness monitor may be fixed to the vapor deposition source moving mechanism, and

the first thickness monitor may be fixed to the vapor deposition unit.

The vapor deposition source may include a heating device, and

the vapor deposition apparatus of the present invention may be configured to perform vapor deposition while controlling the distance and the output of the heating device based on a measurement result from the first thickness monitor.

The vapor deposition source may include a heating device,

the vapor deposition apparatus of the present invention may further include a second thickness monitor, and

the vapor deposition apparatus of the present invention may be configured to perform vapor deposition while controlling the distance and the output of the heating device based on a measurement result from the first thickness monitor and controlling a proportionality coefficient in the control of the distance based on a measurement result from the second thickness monitor.

The vapor deposition apparatus of the present invention may control the output by PID control.

The vapor deposition source may include a crucible provided with an opening, and

the portion designed to eject a vaporized material may be the opening.

The vapor deposition apparatus of the present invention may further include a transfer mechanism configured to move at least one of the substrate and the vapor deposition source relatively to the other in a direction perpendicular to the normal direction of the substrate.

The vapor deposition unit may include the vapor deposition source and a mask, and

the transfer mechanism may move at least one of the substrate and the vapor deposition unit relatively to the other.

The vapor deposition apparatus of the present invention may further include a mask, and

the transfer mechanism may move at least one of the vapor deposition source and the substrate to which the mask is attached, relatively to the other.

The vapor deposition apparatus of the present invention may further include a mask and a substrate holder with a rotating mechanism designed to rotate the substrate to which the mask is attached.

Another aspect of the present invention may be a vapor deposition method, including

a vapor deposition step of forming a film on a substrate,

the vapor deposition step being performed by the vapor deposition apparatus of the present invention.

Yet another aspect of the present invention may be a method for producing an organic electroluminescent element, including

a vapor deposition step of forming a film by the vapor deposition apparatus of the present invention.

The present invention can provide a vapor deposition apparatus, a vapor deposition method, and a method for producing an organic electroluminescent element which can control the vapor deposition rate on the substrate in the entire vapor deposition region with excellent precision.

### BRIEF DESCRIPTION OF THE DRAWINGS

FIG. 1 is a schematic cross-sectional view of an organic EL display including an organic EL element produced by a method for producing an organic EL element according to Embodiment 1.

FIG. 2 is a schematic plan view illustrating the structure in the display region of the organic EL display illustrated in FIG. 1.

FIG. 3 is a schematic cross-sectional view illustrating the structure of the TFT substrate of the organic EL display illustrated in FIG. 1, and corresponds to a view of a cross section taken along the A-B line in FIG. 2.

FIG. 4 is a flowchart for explaining the steps of producing an organic EL display of Embodiment 1.

FIG. 5 is a schematic view illustrating the basic structure of a vapor deposition apparatus of Embodiment 1.

FIG. 6 is a schematic view for explaining control systems of the vapor deposition apparatus of Embodiment 1.

FIG. 7 is a view schematically illustrating one example of changes with time of the first vapor deposition rate in Embodiment 1.

FIG. 8 is a schematic view for explaining a control system of a vapor deposition apparatus of Embodiment 4.

FIG. 9 is a view schematically illustrating one example of changes with time in the vapor deposition rate and a substrate-vapor deposition source distance in Embodiment 4.

FIG. 10 is a view schematically illustrating the relation between the output value of the substrate-vapor deposition source distance and the measurement results from the thickness monitor in Embodiment 4.

FIG. 11 is a schematic view illustrating the basic structure of a vapor deposition apparatus of Example 1.

FIG. 12 is a schematic plan view of the vapor deposition apparatus of Example 1.

FIG. 13 is a schematic plan view of an alternative example of the vapor deposition apparatus of Example 1.

FIG. 14 is a schematic view for explaining the change in pattern when Ts is changed in Example 1.

FIG. 15 is a schematic view for explaining the influence of a change in Ts on the vapor deposition region in Example 1.

FIG. 16 is a graph showing the relation between Ts and a thickness distribution of a vapor deposition film in Example 1.

FIG. 17 is a graph showing each change ratio of the film thickness obtained at adjusted Ts to that obtained at Ts reference in Example 1.

FIG. 18 is a schematic view illustrating the basic structure of a vapor deposition apparatus of Example 2.

FIG. 19 is a schematic view illustrating the basic structure of a vapor deposition apparatus of Example 3.

FIG. 20 is a schematic plan view of vapor deposition sources provided to the vapor deposition apparatus of Example 3.

FIG. 21 is a graph showing the relation between Ts and a thickness distribution of the vapor deposition film in Example 3.

FIG. 22 is a graph showing each change ratio of the film thickness obtained at adjusted Ts to that obtained at Ts reference in Example 3.

FIG. 23 is a schematic view illustrating the basic structure of a scanning vapor deposition apparatus of Comparative Embodiment 1.

FIG. 24 is a graph showing the relation between a heater temperature and a vapor deposition rate in the scanning vapor deposition apparatus of Comparative Embodiment 1.

FIG. 25 is a schematic view illustrating the basic structure of a film formation apparatus described in Patent Literature 1.

FIG. 26 is another schematic view illustrating the basic structure of the film formation apparatus described in Patent Literature 1.

### DETAILED DESCRIPTION OF THE INVENTION

Hereinafter, the present invention will be described in more detail based on embodiments with reference to the drawings. The present invention, however, is not limited to these embodiments.

The present embodiment mainly describes the method for producing an RGB full-color display organic EL element in which light is emitted from the TFT substrate side, and an organic EL display including an organic EL element produced by the production method. Yet, the present embodiment is applicable to methods for producing organic EL elements of the other types.

First, the overall structure of the organic EL display of the present embodiment is described.

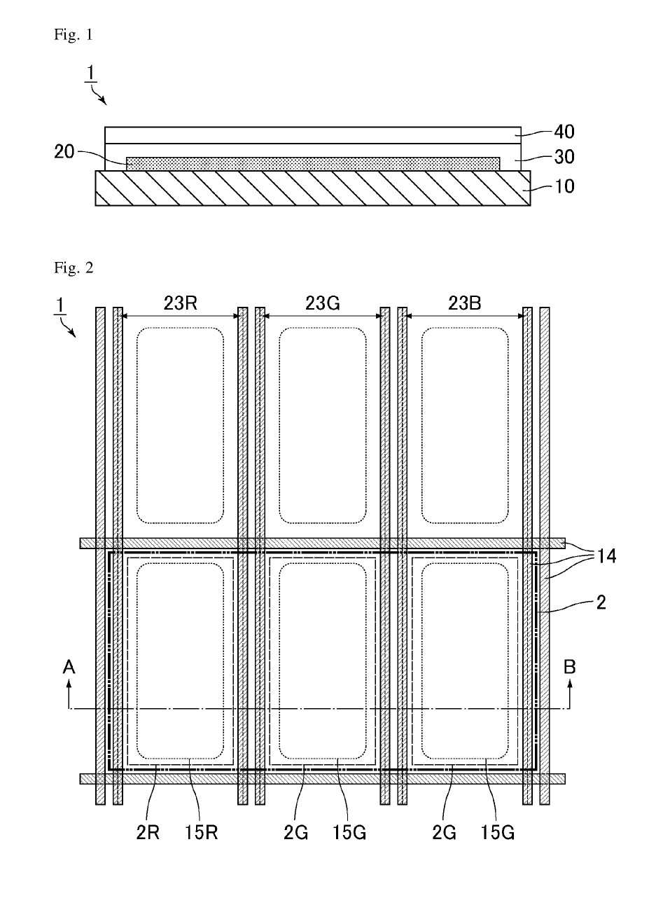

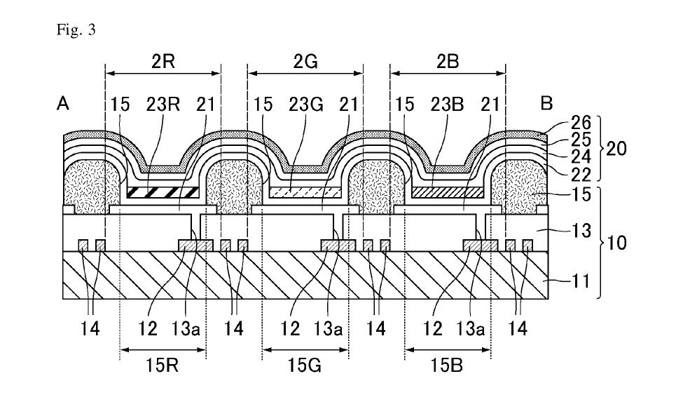

FIG. 1 is a schematic cross-sectional view of an organic EL display including an organic EL element produced by a method for producing an organic EL element according to Embodiment 1. FIG. 2 is a schematic plan view illustrating the structure in the display region of the organic EL display illustrated in FIG. 1. FIG. 3 is a schematic cross-sectional view illustrating the structure of the TFT substrate of the organic EL display illustrated in FIG. 1, and corresponds to a view of a cross section taken along the A-B line in FIG. 2.

As illustrated in FIG. 1, an organic EL display 1 of the present embodiment includes a TFT substrate 10 provided with TFTs 12 (cf. FIG. 3), organic EL elements 20 that are provided on the TFT substrate 10 and connected to the TFTs 12, an adhesive layer 30 covering the organic EL elements 20, and a sealing substrate 40 disposed on the adhesive layer 30.

When the sealing substrate 40 and the TFT substrate 10 with the organic EL elements 20 stacked thereon are attached by the adhesive layer 30, the organic EL elements 20 are sealed between the substrates 10 and 40 constituting one pair. Thereby, oxygen and moisture in the outside air are prevented from entering the organic EL elements 20.

As illustrated in FIG. 3, the TFT substrate 10 includes a transparent insulating substrate 11 (e.g. glass substrate) as a supporting substrate. As illustrated in FIG. 2, conductive lines 14 are formed on the insulating substrate 11, and include gate lines that are provided in the horizontal direction and signal lines that are provided in the vertical direction and cross the gate lines. The gate lines are connected to a gate-line drive circuit (not illustrated) configured to drive the gate lines. The signal lines are connected to a signal-line drive circuit (not illustrated) configured to drive the signal lines.

The organic EL display 1 is an active-matrix display device providing RGB full-color display, and each region defined by the conductive lines 14 includes a sub-pixel (dot) 2R, 2G, or 2B in a color red (R), green (G), or blue (B). The sub-pixels 2R, 2G, and 2B are arranged in a matrix. In each of the sub-pixels 2R, 2G, and 2B in the respective colors, an organic EL element 20 of the corresponding color and a light-emitting region are formed.

The red, green, and blue sub-pixels 2R, 2G, and 2B respectively emit red light, green light, and blue light, and each group of the three sub-pixels 2R, 2G, and 2B form one pixel 2.

The sub-pixels 2R, 2G, and 2B are respectively provided with openings 15R, 15G, and 15B, and the openings 15R, 15G, and 15B are covered with red, green, and blue light-emitting layers 23R, 23G, and 23B, respectively. The light-emitting layers 23R, 23G, and 23B form stripes in the vertical direction. The patterned light-emitting layers 23R, 23G, and 23B are formed separately for one color at one time by vapor deposition. The openings 15R, 15G, and 15B are described later.

Each of the sub-pixels 2R, 2G, and 2B is provided with a TFT 12 connected to a first electrode 21 of the organic EL element 20. The luminescence intensity of each of the sub-pixels 2R, 2G, and 2B is determined based on scanning and selection using the conductive lines 14 and the TFTs 12. As described above, the organic EL display 1 provides image display by selectively allowing the organic EL elements 20 in the individual colors to emit light, using the TFTs 12.

Next, the structures of the TFT substrate 10 and the organic EL elements 20 are described in detail. First, the TFT substrate 10 is described.

As illustrated in FIG. 3, the TFT substrate 10 is provided with the TFTs 12 (switching elements) and the conductive lines 14 which are formed on the insulating substrate 11; an interlayer film (interlayer insulating film, flattening film) 13 that covers the TFTs and conductive lines; and an edge cover 15 which is an insulating layer formed on the interlayer film 13.

The TFTs 12 are formed for the respective sub-pixels 2R, 2G, and 2B. Here, since the structure of the TFTs 12 may be a common structure, layers in the TFTs 12 are not illustrated or described.

The interlayer film 13 is formed on the insulating substrate 11 to cover the entire region of the insulating substrate 11. On the interlayer film 13, the first electrodes 21 of the organic EL elements 20 are formed. Also, the interlayer film 13 is provided with contact holes 13a for electrically connecting the first electrodes 21 to the TFTs 12. In this manner, the TFTs 12 are electrically connected to the organic EL elements 20 via the contact holes 13a.

The edge cover 15 is formed to prevent a short circuit between the first electrode 21 and a second electrode 26 of each organic EL element 20 when the organic EL layer is thin or concentration of electric fields occurs at the end of the first electrode 21. The edge cover 15 is therefore formed to partly cover the ends of the first electrodes 21.

The above-mentioned openings 15R, 15G, and 15B are formed in the edge cover 15. These openings 15R, 15G, and 15B of the edge cover 15 respectively serve as light-emitting regions of the sub-pixels 2R, 2G, and 2B. In other words, the sub-pixels 2R, 2G, and 2B are separated by the edge cover 15 which has insulation properties. The edge cover 15 functions also as an element-separation film.

Next, the organic EL elements 20 are described.

The organic EL elements 20 are light-emitting elements capable of providing a high-luminance light when driven by low-voltage direct current, and each include the first electrode 21, the organic EL layer, and the second electrode 26 which are stacked in the stated order.

The first electrode 21 is a layer having a function of injecting (supplying) holes into the organic EL layer. The first electrode 21 is connected to the TFT 12 via the contact hole 13a as described above.

As illustrated in FIG. 3, the organic EL layer between the first electrode 21 and the second electrode 26 includes a hole injection/hole transport layer 22, the light-emitting layer 23R, 23G, or 23B, an electron transport layer 24, and an electron injection layer 25 in the stated order from the first electrode 21 side.

The above stacking order is for the case that the first electrode 21 is an anode and the second electrode 26 is a cathode. In the case that the first electrode 21 is a cathode and the second electrode 26 is an anode, the stacking order for the organic EL layer is reversed.

The hole injection layer has a function of increasing the hole injection efficiency to the light-emitting layer 23R, 23G, or 23B. The hole transport layer has a function of increasing the hole transport efficiency to the light-emitting layer 23R, 23G, or 23B. The hole injection/hole transport layer 22 is uniformly formed on the entire display region of the TFT substrate 10 to cover the first electrodes 21 and the edge cover 15.

The present embodiment is described based on an example in which an integrated form of a hole injection layer and a hole transport layer, namely the hole injection/hole transport layer 22, is provided as the hole injection layer and the hole transport layer. The present embodiment, however, is not particularly limited to this example. The hole injection layer and the hole transport layer may be formed as layers independent of each other.

On the hole injection/hole transport layer 22, the light-emitting layers 23R, 23G, and 23B are formed correspondingly to, respectively, sub-pixels 2R, 2G, and 2B, to cover the openings 15R, 15G, and 15B of the edge cover 15.

Each of the light-emitting layers 23R, 23G, and 23B has a function of emitting light by recombining holes injected from the first electrode 21 side and electrons injected from the second electrode 26 side. Each of the light-emitting layers 23R, 23G, and 23B is formed from a material exhibiting a high luminous efficiency, such as a low-molecular fluorescent dye and a metal complex.

The electron transport layer 24 has a function of increasing the electron transport efficiency from the second electrode 26 to each of the light-emitting layers 23R, 23G, and 23B. The electron injection layer 25 has a function of increasing the electron injection efficiency from the second electrode 26 to each of the light-emitting layers 23R, 23G, and 23B.

The electron transport layer 24 is uniformly formed on the entire display region of the TFT substrate 10 to cover the light-emitting layers 23R, 23G, and 23B, and the hole injection/hole transport layer 22. Also, the electron injection layer 25 is uniformly formed on the entire display region of the TFT substrate 10 to cover the electron transport layer 24.

The electron transport layer 24 and the electron injection layer 25 may be formed as layers independent of each other, or may be formed as an integrated layer. That is, the organic EL display 1 may be provided with an electron transport/electron injection layer in place of the electron transport layer 24 and the electron injection layer 25.

The second electrode 26 has a function of injecting electrons to the organic EL layer. The second electrode 26 is uniformly formed on the entire display region of the TFT substrate 10 to cover the electron injection layer 25.

Here, organic layers other than the light-emitting layers 23R, 23G, and 23B are not essential layers for the organic EL layer, and may be appropriately formed depending on the required properties of the organic EL elements 20. The organic EL layer may additionally include a carrier blocking layer. For example, a hole blocking layer may be added as a carrier blocking layer between the light-emitting layer 23R, 23G, or 23B and the electron transport layer 24 such that holes can be prevented from reaching the electron transport layer 24, and thereby the light-emitting efficiency is enhanced.

The structure of the organic EL elements 20 may be any of the following structures (1) to (8).

(1) First electrode/light-emitting layer/second electrode

(2) First electrode/hole transport layer/light-emitting layer/electron transport layer/second electrode

(3) First electrode/hole transport layer/light-emitting layer/hole blocking layer/electron transport layer/second electrode

(4) First electrode/hole transport layer/light-emitting layer/hole blocking layer/electron transport layer/electron injection layer/second electrode

(5) First electrode/hole injection layer/hole transport layer/light-emitting layer/electron transport layer/electron injection layer/second electrode

(6) First electrode/hole injection layer/hole transport layer/light-emitting layer/hole blocking layer/electron transport layer/second electrode

(7) First electrode/hole injection layer/hole transport layer/light-emitting layer/hole blocking layer/electron transport layer/electron injection layer/second electrode

(8) First electrode/hole injection layer/hole transport layer/electron blocking layer (carrier blocking layer)/light-emitting layer/hole blocking layer/electron transport layer/electron injection layer/second electrode

The hole injection layer and the hole transport layer may be integrated as described above. Also, the electron transport layer and the electron injection layer may be integrated.

The structure of the organic EL elements 20 is not particularly limited to the structures (1) to (8), and any desired layer structure can be used depending on the required properties of the organic EL elements 20.

Next, the method for producing the organic EL display 1 is described.

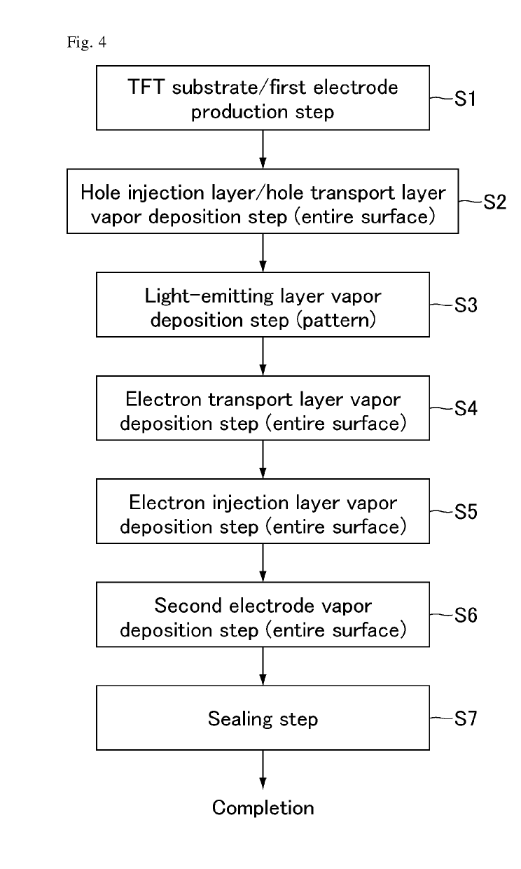

FIG. 4 is a flowchart for explaining the steps of producing an organic EL display of Embodiment 1.

As illustrated in FIG. 4, the method for producing an organic EL display according to the present embodiment includes, for example, a TFT substrate/first electrode production step S1, a hole injection layer/hole transport layer vapor deposition step S2, a light-emitting layer vapor deposition step S3, an electron transport layer vapor deposition step S4, an electron injection layer vapor deposition step S5, a second electrode vapor deposition step S6, and a sealing step S7.

Hereinafter, the production steps of the components described above with reference to FIGS. 1 to 3 are described by following the flowchart shown in FIG. 4. The size, material, shape, and the other designs of each component described in the present embodiment are merely examples which are not intended to limit the scope of the present invention.

As described above, the stacking order described in the present embodiment is for the case that the first electrode 21 is an anode and the second electrode 26 is a cathode. In the case that the first electrode 21 is a cathode and the second electrode 26 is an anode, the stacking order for the organic EL layer is reversed. Similarly, the materials of the first electrode 21 and the second electrode 26 are changed to the corresponding materials.

First, as illustrated in FIG. 3, a photosensitive resin is applied to the insulating substrate 11 on which components such as the TFTs 12 and the conductive lines 14 are formed by a common method, and the photosensitive resin is patterned by photolithography, so that the interlayer film 13 is formed on the insulating substrate 11.

The insulating substrate 11 may be, for example, a glass substrate or a plastic substrate with a thickness of 0.7 to 1.1 mm, a Y-axial direction length (vertical length) of 400 to 500 mm, and an X-axis direction length (horizontal length) of 300 to 400 mm.

The material of the interlayer film 13 can be, for example, a resin such as an acrylic resin and a polyimide resin. Examples of the acrylic resin include the OPTMER series from JSR Corporation. Examples of the polyimide resin include the PHOTONEECE series from Toray Industries, Inc. The polyimide resin, however, is typically colored, not transparent. For this reason, in the case of producing a bottom-emission organic EL display device as the organic EL display 1 as illustrated in FIG. 3, a transparent resin such as an acrylic resin is more suitable for the interlayer film 13.

The thickness of the interlayer film 13 may be any value that can compensate for the steps formed by the TFTs 12. For example, the thickness may be about 2 μm.

Next, the contact holes 13a for electrically connecting the first electrodes 21 to the TFTs 12 are formed in the interlayer film 13.

A conductive film (electrode film), for example an indium tin oxide (ITO) film, is formed to a thickness of 100 nm by sputtering or the like method.

A photoresist is applied to the ITO film, and the photoresist is patterned by photolithography. Then, the ITO film is etched with ferric chloride as an etching solution. The photoresist is removed by a resist removing solution, and the substrate is washed. Thereby, the first electrodes 21 are formed in a matrix on the interlayer film 13.

The conductive film material used for the first electrodes 21 may be, for example, a transparent conductive material such as ITO, indium zinc oxide (IZO), and gallium-added zinc oxide (GZO); or a metal material such as gold (Au), nickel (Ni), and platinum (Pt).

The stacking method for the conductive film other than sputtering may be vacuum vapor deposition, chemical vapor deposition (CVD), plasma CVD, or printing.

The thickness of each first electrode 21 is not particularly limited, and may be 100 nm as described above, for example.

The edge cover 15 is then formed to a thickness of about 1 μm, for example, by the same method as that for the interlayer film 13. The material of the edge cover 15 can be the same insulating material as that of the interlayer film 13.

By the above procedure, the TFT substrate 10 and the first electrodes 21 are produced (S1).

Next, the TFT substrate 10 obtained in the above step is subjected to the reduced-pressure baking for dehydration, and to oxygen plasma treatment for surface washing of the first electrodes 21.

With a vapor deposition apparatus described later, a hole injection layer and a hole transport layer (hole injection/hole transport layer 22 in the present embodiment) are vapor-deposited on the entire display region of the TFT substrate 10 (S2).

Specifically, an open mask which is open to the entire display region is subjected to alignment control relative to the TFT substrate 10, and the open mask is attached closely to the TFT substrate 10. The material dispersed from the vapor deposition source is then evenly vapor-deposited on the entire display region via the opening of the open mask, while both the TFT substrate 10 and the open mask are rotated.

Here, the vapor deposition to the entire display region means continuous vapor deposition over sub-pixels which are in different colors from the adjacent sub-pixels.

Examples of the material of the hole injection layer and the hole transport layer include benzine, styrylamine, triphenylamine, porphyrin, triazole, imidazole, oxadiazole, polyarylalkane, phenylenediamine, arylamine, oxazole, anthracene, fluorenone, hydrazone, stilbene, triphenylene, azatriphenylene, and derivatives thereof; polysilane-based compounds; vinylcarbazole-based compounds; and conjugated heterocyclic monomers, oligomers, or polymers, such as thiophene-based compounds and aniline-based compounds.

The hole injection layer and the hole transport layer may be integrated as described above, or may be formed as layers independent of each other. The thickness of each layer is, for example, 10 to 100 nm.

In the case of forming the hole injection/hole transport layer 22 as the hole injection layer and the hole transport layer, the material of the hole injection/hole transport layer 22 may be, for example, 4,4′-bis[N-(1-naphthyl)-N-phenylamino]biphenyl (α-NPD). The thickness of the hole injection/hole transport layer 22 may be, for example, 30 nm.

On the hole injection/hole transport layer 22, the light-emitting layers 23R, 23G, and 23B are separately formed (by patterning) to correspond to the sub-pixels 2R, 2G, and 2B, and cover the openings 15R, 15G, and 15B of the edge cover 15, respectively (S3).

As described above, a material with a high light-emitting efficiency, such as a low-molecular fluorescent dye or a metal complex, is used for each of the light-emitting layers 23R, 23G, and 23B.

Examples of the material of the light-emitting layers 23R, 23G, and 23B include anthracene, naphthalene, indene, phenanthrene, pyrene, naphthacene, triphenylene, anthracene, perylene, picene, fluoranthene, acephenanthrylene, pentaphene, pentacene, coronene, butadiene, coumarin, acridine, stilbene, and derivatives thereof; a tris(8-quinolinolato)aluminum complex; a bis(benzoquinolinolato)beryllium complex; a tri(dibenzoylmethyl)phenanthroline europium complex; and ditolylvinyl biphenyl.

The thickness of each of the light-emitting layers 23R, 23G, and 23B is 10 to 100 nm, for example.

By the same method as that in the hole injection/hole transport layer vapor deposition step S2, the electron transport layer 24 is vapor-deposited on the entire display region of the TFT substrate 10 to cover the hole injection/hole transport layer 22 and the light-emitting layers 23R, 23G, and 23B (S4).

By the same method as that in the hole injection/hole transport layer vapor deposition step S2, the electron injection layer 25 is vapor-deposited on the entire display region of the TFT substrate 10 to cover the electron transport layer 24 (S5).

Examples of the material of the electron transport layer 24 and the electron injection layer 25 include quinoline, perylene, phenanthroline, bisstyryl, pyrazine, triazole, oxazol, oxadiazole, fluorenone, and derivatives thereof and metal complexes thereof; and lithium fluoride (LiF).

Specific examples thereof include Alq₃ (tris(8-hydroxyquinoline)aluminum), anthracene, naphthalene, phenanthrene, pyrene, anthracene, perylene, butadiene, coumarin, acridine, stilbene, 1,10-phenanthroline, and derivatives thereof and metal complexes thereof; and LiF.

As described above, the electron transport layer 24 and the electron injection layer 25 may be integrated or may be formed as independent layers. The thickness of each layer is 1 to 100 nm, for example, and is preferably 10 to 100 nm. Also, the total thickness of the electron transport layer 24 and the electron injection layer 25 is 20 to 200 nm, for example.

Typically, Alq₃ is used as the material of the electron transport layer 24, and LiF is used as the material of the electron injection layer 25. For example, the thickness of the electron transport layer 24 is 30 nm, and the thickness of the electron injection layer 25 is 1 nm.

By the same method as that in the hole injection/hole transport layer vapor deposition step S2, the second electrode 26 is vapor-deposited on the entire display region of the TFT substrate 10 to cover the electron injection layer 25 (S6). As a result, the organic EL elements 20 each including the organic EL layer, the first electrode 21, and the second electrode 26 are formed on the TFT substrate 10.

For the material (electrode material) of the second electrode 26, a material such as a metal with a small work function is suitable. Examples of such an electrode material include magnesium alloys (e.g. MgAg), aluminum alloys (e.g. AlLi, AlCa, AlMg), and metal calcium. The thickness of the second electrode 26 is 50 to 100 nm, for example.

Typically, the second electrode 26 is formed from a 50-nm-thick aluminum thin film.

Subsequently, as illustrated in FIG. 1, the TFT substrate 10 with the organic EL elements 20 formed thereon and the sealing substrate 40 are attached by the adhesive layer 30, so that the organic EL elements 20 are sealed.

The sealing substrate 40 is, for example, an insulating substrate (e.g. glass substrate or plastic substrate) with a thickness of 0.4 to 1.1 mm.

Here, the vertical length and the horizontal length of the sealing substrate 40 may be appropriately adjusted to suit the size of the subject organic EL display 1. The organic EL elements 20 may be sealed using an insulating substrate of substantially the same size as that of the insulating substrate 11 of the TFT substrate 10, and these substrates may be cut according to the size of the subject organic EL display 1.

Also, the method for sealing the organic EL elements 20 is not particularly limited to the above method, and may be any other sealing method. Examples of the other sealing method include a method of sealing the elements using an engraved glass plate as the sealing substrate 40 by a material such as a sealing resin or a glass frit applied in a frame-like shape; and a method of filling the space between the TFT substrate 10 and the sealing substrate 40 with a resin.

Also, on the second electrode 26, a protective film (not illustrated) may be provided to prevent oxygen and moisture in the outside air from entering the organic EL elements 20.

The protective film can be formed from an insulating or conductive material. Examples of such a material include silicon nitride and silicon oxide. The thickness of the protective film is 100 to 1000 nm, for example.

These steps produce the organic EL display 1.

In this organic EL display 1, holes are injected by the first electrodes 21 into the organic EL layer when the TFTs 12 are turned on by signals input through the conductive lines 14. Meanwhile, electrons are injected by the second electrode 26 into the organic EL layer, and the holes and electrons are recombined in each of the light-emitting layers 23R, 23G, and 23B. The energy from the recombination of the holes and electrons excites the luminescent materials, and when the excited materials go back to the ground state, light is emitted. Controlling the luminance of the light emitted from each of the sub-pixels 2R, 2G, and 2B enables display of a predetermined image.

Next, the method for producing an organic EL element according to the present embodiment, particularly the vapor deposition apparatus of Embodiment 1 suitable for the vapor deposition steps S2 to S6, is described.

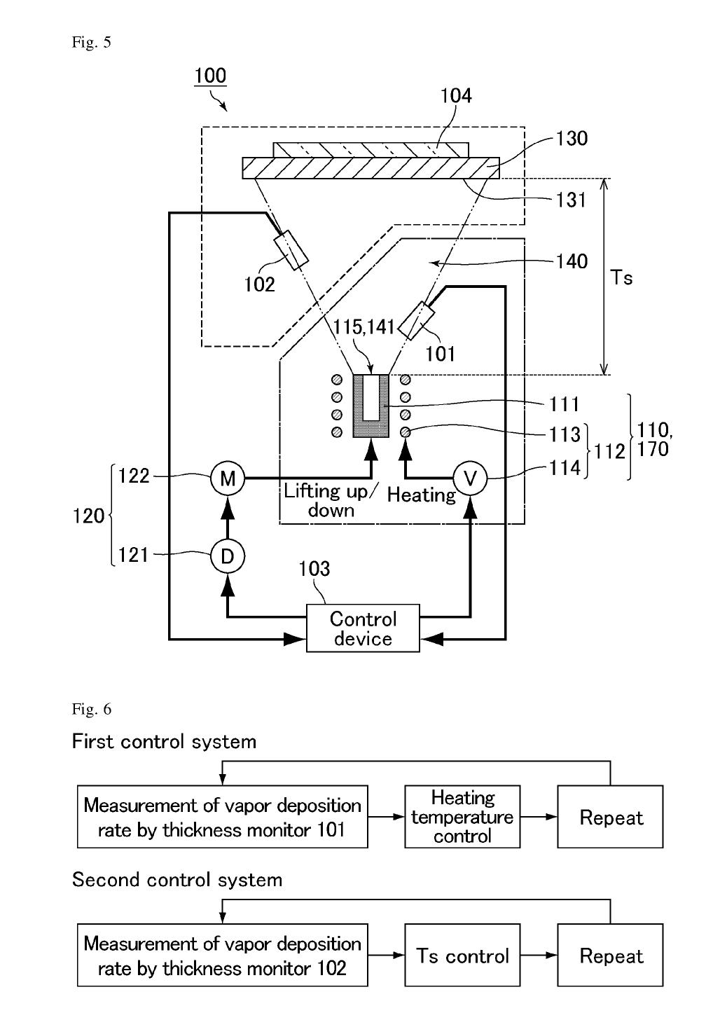

FIG. 5 is a schematic view illustrating the basic structure of a vapor deposition apparatus of Embodiment 1.

As illustrated in FIG. 5, a vapor deposition apparatus 100 of the present embodiment includes a vacuum chamber (not illustrated), a vapor deposition unit 170 provided with a vapor deposition source (evaporation source) 110, thickness monitors (rate monitors) 101 and 102, a control device 103, a vapor deposition source moving mechanism 120, and a substrate holder 104. The vapor deposition apparatus 100 includes a motor driving device 121 and a vapor deposition source lifting mechanism 122 which constitute the vapor deposition source moving mechanism 120.

In the present embodiment, the thickness monitor 101 corresponds to the second thickness monitor of the vapor deposition apparatus of the present invention, and the thickness monitor 102 corresponds to the first thickness monitor of the vapor deposition apparatus of the present invention.

The vacuum chamber is a vessel that provides inside a substrate treatment environment where the degree of vacuum that allows vacuum vapor deposition is maintained. The vacuum chamber includes inside the vapor deposition source 110, the thickness monitors 101 and 102, the vapor deposition source lifting mechanism 122, and the substrate holder 104.

The substrate holder 104 is a component that holds a substrate (film formation target substrate) 130 on which a film is formed by the vapor deposition apparatus 100. The substrate holder 104 is provided in an upper portion within the vacuum chamber.

The vapor deposition source 110 is a component that heats a material to be vapor-deposited (preferably an organic material) to vaporize the material, i.e., to evaporate or sublimate the material, and then eject the vaporized material into the inside of the vacuum chamber. More specifically, the vapor deposition source 110 includes a heat resistant vessel (e.g., crucible 111) designed to house the material, a heating device 112 (e.g., a heater 113 and a heating power supply 114) configured to heat the material. The crucible 111 is provided with an opening 115 at the top thereof. The vapor deposition source 110 heats the material in the vessel (e.g. crucible 111) using the heating device 112 to vaporize the material, and the vaporized material (hereinafter, also referred to as vapor deposition particles) is ejected from the opening 115 upwardly. As a result, a vapor deposition stream 140, which is a stream of the vapor deposition particles, is generated from the opening 115. The vapor deposition stream 140 spreads isotropically from the opening 115. The vapor deposition source 110 is provided in a lower portion within the vacuum chamber.

The vapor deposition source 110 may be any vapor deposition source such as a point vapor deposition source (point source), a line vapor deposition source (line source), or a surface vapor deposition source. Also, the method for heating the vapor deposition source 110 may be any method such as resistive heating, an electron beam method, laser evaporation, high frequency induction heating, or an arc method. The density distribution of the vapor deposition stream 140, for example the N value of the vapor deposition source 110, is not particularly limited and may be appropriately set. Furthermore, the range in the distribution of the vapor deposition stream 140 which is actually used for the vapor deposition is not particularly limited, and may also be appropriately set.

The vapor deposition unit 170 may include a mask provided with multiple openings in the desired pattern and disposed between the substrate 130 and the vapor deposition source 110.

The thickness monitors 101 and 102 are devices that measure the vapor deposition rate. At least part of each of the thickness monitors 101 and 102, for example a sensor portion, is disposed at a position to which the vapor deposition particles ejected from the vapor deposition source 110 can directly fly, such as a position between the substrate 130 and the vapor deposition source 110. The kind and structure of each of the thickness monitors 101 and 102 are not particularly limited. The thickness monitors 101 and 102 each preferably include a sensor portion utilizing a quartz resonator. Since the oscillating frequency of the quartz resonator is correlated to the thickness of the film formed on the quartz resonator, the vapor deposition rate can be measured with high precision based on the amount of change in the oscillating frequency.

To the control device 103 is input the detection result from the thickness monitor 102, in particular, the vapor deposition rate measured by the thickness monitor 102. Based on the detection result, the control device 103 calculates the distance required between a portion (hereinafter, also referred to as an ejection portion) 141 of the vapor deposition source 110 from which the vaporized material is ejected and a surface (hereinafter, also referred to as a vapor deposition target surface) 131 of the substrate 130 on which vapor deposition is performed. The calculation result is then output to the vapor deposition source moving mechanism 120 as a height control signal. The ejection portion 141 may be the opening 115 of the crucible 111.

The vapor deposition source moving mechanism 120 is configured to move the vapor deposition source 110 to change the height of the ejection portion 141. The vapor deposition source moving mechanism 120 moves the vapor deposition source 110 by the required distance to adjust the height of the ejection portion 141 to the desired height, based on the height control signal input from the control device 103. The specific components of the vapor deposition source moving mechanism 120 are not particularly limited. The vapor deposition source moving mechanism 120 can be a general mechanism capable of controlling the height of an object based on a height control signal. The vapor deposition source moving mechanism 120 may move the whole or part of the vapor deposition source 110. For example, the vapor deposition source moving mechanism 120 may move the crucible 111 and the heater 113 integrally without moving the heating power supply 114.

The motor driving device 121 converts a height control signal input from the control device 103 to a drive current for the vapor deposition source lifting mechanism 122 to be driven, and supplies the drive current to the vapor deposition source lifting mechanism 122. For example, the motor driving device 121 is a servomotor driver that performs positional control by pulse input.

The vapor deposition source lifting mechanism 122 is configured to convert the drive current supplied by the motor driving device 121 to a mechanical work (mechanical energy). The vapor deposition source lifting mechanism 122 is connected to the vapor deposition source 110, and moves the vapor deposition source 110 up and down, i.e., lifts it up and down, to change the height of the ejection portion 141. Examples of the specific mechanism of the vapor deposition lifting mechanism 122 include, but are not particularly limited to, a mechanism that includes a motor (e.g., servomotor, stepping motor), a ball screw, and a linear guide. The vapor deposition source lifting mechanism 122 may include a piezoelectric element.

To the control device 103 is also input a detection result from the thickness monitor 101, in particular, the vapor deposition rate measured by the thickness monitor 101. The control device 103 calculates the output (power) of the heating device 112, such as an electric power value to be supplied to the heater 113, for example. The calculation result is then output to the heating device 112 as a temperature control signal.

The vapor deposition apparatus 100 of the present embodiment may be a point source vapor deposition apparatus that performs vapor deposition while rotating the substrate 130 using a point vapor deposition source as the vapor deposition source 110, or may be a scanning vapor deposition apparatus that performs vapor deposition while moving the substrate 130 relatively to the vapor deposition source 110 in one direction. In the case of the point source vapor deposition apparatus, the vapor deposition apparatus 100 of the present embodiment may be provided with a mask (not illustrated) and a substrate holder with a rotating mechanism (not illustrated) designed to rotate the substrate 130 to which the mask is attached. In the case of the scanning vapor deposition apparatus, the vapor deposition apparatus 100 of the present embodiment may include a transfer mechanism (not illustrated) configured to move at least one of the substrate 130 and the vapor deposition source 110 relatively to the other in a direction (transfer direction) perpendicular to the normal direction of the substrate 130.

Next, the movement of the vapor deposition apparatus 100 is described.

First, the substrate 130 is held by the substrate holder 104. The substrate 130 is held such that the vapor deposition target surface 131 faces the vapor deposition source 110. Also, the vapor deposition source 110 contains the material to be vapor-deposited. The material is vaporized (evaporated or sublimated) by the heating device 112 of the vapor deposition source 110 turned on to generate heat. The vaporized material is ejected from the vapor deposition source 110, so that the vapor deposition particles are scattered within the vacuum chamber. The vapor deposition particles reach the substrate 130 and are accumulated on the vapor deposition target surface 131 of the substrate 130. Thereby, the desired material is vapor-deposited on the vapor deposition target surface 131 of the substrate 130.

FIG. 6 is a schematic view for explaining control systems of the vapor deposition apparatus of Embodiment 1.

During vapor deposition, some of the vapor deposition particles ejected from the vapor deposition source 110 reach the thickness monitor 101 or 102. Then, as illustrated in FIG. 6, a first control system including the thickness monitor 101 and a second control system including the thickness monitor 102 each perform feedback control to control the vapor deposition rates which are measured by the thickness monitors 101 and 102. The first control system controls the vapor deposition rate of the vapor deposition stream 140 scattered from the ejection portion 141, i.e., the vapor deposition rate (hereinafter, also referred to as a first vapor deposition rate) of the vapor deposition particles ejected from the ejection portion 141. The second control system controls the substantial vapor deposition rate of the vapor deposition stream 140 (vapor deposition particles) reaching the substrate 130, i.e., the vapor deposition rate (hereinafter, also referred to as the second vapor deposition rate) on the substrate 130. As described above, the first vapor deposition rate is an index indicating the speed at which the vapor deposition particles are ejected from the vapor deposition source 110. The second vapor deposition rate is an index indicating the substantial speed at which the vapor deposition particles actually reach (accumulate on) the substrate 130. The first control system measures the first vapor deposition rate by the thickness monitor 101 and successively outputs the measurement results to the control device 103. The second control system measures the second vapor deposition rate by the thickness monitor 102 and successively outputs the measurement results to the control device 103.

The first control system controls the amount of vapor deposition particles ejected from the vapor deposition source 110 by adjusting the heating temperature for the material, i.e., the output of the heating device 112, based on the measurement result from the thickness monitor 101. The second control system controls the amount of vapor deposition particles reaching the substrate 130 by changing the height of the ejection portion 141 based on the measurement result from the thickness monitor 102 to adjust the distance (hereinafter, also referred to as a substrate-vapor deposition source distance) Ts between the ejection portion 141 and the vapor deposition target surface 131 of the substrate 130. During vapor deposition, such control is repeatedly performed by each of the control systems.

The first control system controls output of the heating device 112 in order to adjust the heating temperature for the material. Here, the behavior of the temperature of the vessel (e.g. crucible 111) that houses the material is determined depending on various conditions such as the control values input before the determination and the physical properties of the material. That is, the first control system can be regarded as a dynamic control system with a great time delay between the control operation and the change in the behavior of the first vapor deposition rate. Therefore, the first control system preferably performs proportional integral derivative (PID) control.

Meanwhile, the second control system controls the height of the ejection portion 141 in order to adjust the substrate-vapor deposition source distance Ts. The height of the ejection portion 141 is determined based on a height control signal. When a height control signal is input to the vapor deposition source moving mechanism 120, the height of the ejection portion 141 is changed instantaneously. When the height of the ejection portion 141 is changed, the second vapor deposition rate measured by the thickness monitor 102 instantaneously changes to a value corresponding to the height of the ejection portion 141. That is, the second control system can be regarded as a static control system in which the second vapor deposition rate does not depend on the past control history and depends only on the control value of the moment. Hence, the second control system preferably performs control which corrects the differences between the measured values and the target values one by one, such as proportional control (P control). In this case, the expected precision of the control increases as the time of one cycle for feedback reduces. If the time required for the feedback becomes long due to the calculation of the operation amount, i.e., the substrate-vapor deposition source distance Ts, or the other factors, the control precision may decrease. In such a case, the second control system preferably performs PID control.

Conventionally, since the vapor deposition rate has been controlled only by a dynamic control system with a large time delay, it has been difficult to control the vapor deposition rate stably with high precision. In contrast, in the present embodiment, since a dynamic control system with a large time delay and a static control system with a very small time delay are combined, each vapor deposition rate, particularly the second vapor deposition rate, i.e., the vapor deposition rate on the substrate 130, can be controlled with very high precision.

Hereinafter, the method for controlling each vapor deposition rate performed by each control system is further described. The case of performing PID control is described for the first control system, and the case of performing proportional control is described for the second control system.

In the first control system, the control device 103 predict the future first vapor deposition rate (predicted rate) based on the first vapor deposition rate (measured rate) input from the thickness monitor 101, and compares the predicted rate with the preset target first vapor deposition rate (target rate). In the case that the predicted rate is higher than the target rate, the control device 103 reduces the output (e.g., electric power to be supplied to the heater 113) of the heating device 112 by the amount required based on the difference between the rates. By reducing the output of the heating device 112, the heating temperature for the material is decreased to reduce the amount of the material to be vaporized. As a result, the first vapor deposition rate drops. In contrast, in the case that the predicted rate is lower than the target rate, the control device 103 increases the output (e.g., electric power to be supplied to the heater 113) of the heating device 112 by the amount required based on the difference between the rates. By increasing the output of the heating device 112, the heating temperature for the material is raised to increase the amount of the material to be vaporized. As a result, the first vapor deposition rate rises.

Generally, the relation between the heating temperature for the material and the vapor deposition rate is not proportional. Thus, it is preferred that the first control system performs the PID control and determines the heating temperature for the material, i.e., the output of the heating device 112, while predicting the further first vapor deposition rate.

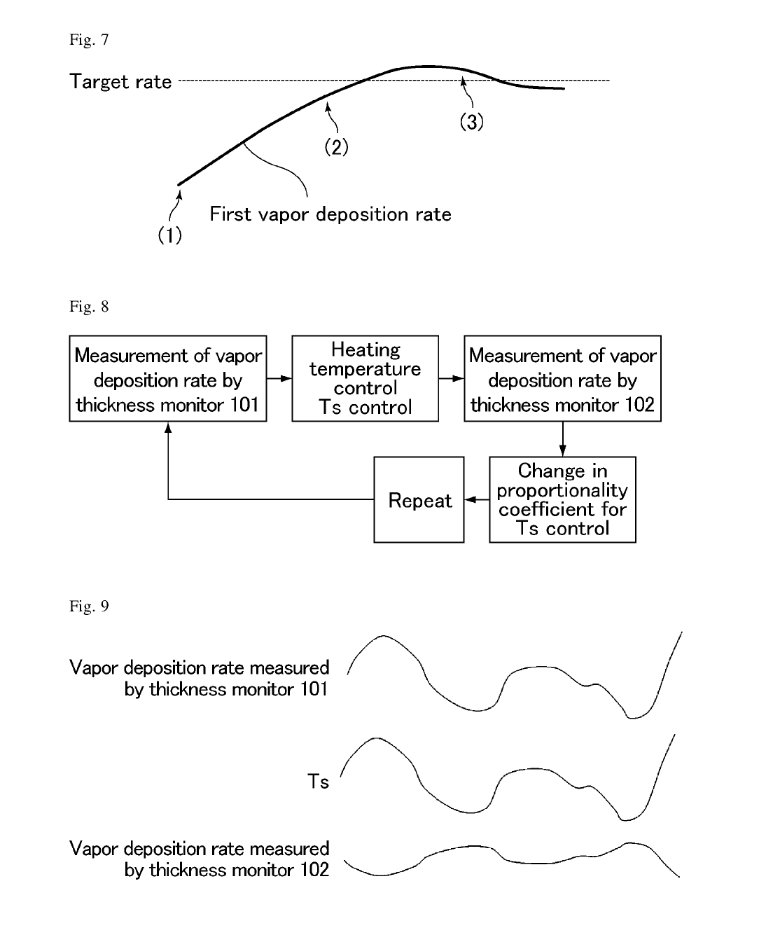

FIG. 7 is a view schematically illustrating one example of changes with time of the first vapor deposition rate in Embodiment 1.

As illustrated in FIG. 7, when, for example, the first vapor deposition rate is lower than the target rate and the output of the heating device 112 is increased (in FIG. 7, the point (1)), the first vapor deposition rate rises. Then, in the case that the first vapor deposition rate is predicted to be equal to or higher than the target rate if the same conditions are to be maintained, the output of the heating device 112 is preferably reduced before the first vapor deposition rate rises to the target rate (in FIG. 7, the point (2)). Also, when the first vapor deposition rate is equal to or higher than the target rate and the output of the heating device 112 is reduced, the first vapor deposition rate drops. Then, in the case that the first vapor deposition rate is predicted to be lower than the target rate if the same conditions are to be maintained, the output of the heating device 112 is preferably increased before the first vapor deposition rate drops to the target vapor deposition rate (in FIG. 7, the point (3)).

In the second control system, the control device 103 compares the second vapor deposition rate (measured rate) input from the thickness monitor 102 with the preset target second vapor deposition rate (target rate). In the case that the measured rate is higher than the target rate, the control device 103 lowers the height of the ejection portion 141 by the amount required based on the difference between the rates. Generally, the density of vapor deposition particles is inversely proportional to the square of the distance from the vapor deposition source in each case of using a point vapor deposition source, a line vapor deposition source, or a surface vapor deposition source. Hence, lowering the height of the ejection portion 141 increases the substrate-vapor deposition source distance Ts, reducing the density of vapor deposition particles on the vapor deposition target surface 131. As a result, the second vapor deposition rate drops. In contrast, in the case that the measured rate is lower than the target rate, the control device 103 raises the height of the ejection portion 141 by the amount required based on the difference between the rates. Raising the height of the ejection portion 141 shortens the substrate-vapor deposition source distance Ts, increasing the density of vapor deposition particles on the vapor deposition target surface 131. As a result, the second vapor deposition rate rises.

Since the control of the second vapor deposition rate by the second control system does not involve a phenomenon such as heat exchange, this control characteristically shows very high response performance with a small time constant. Hence, by performing real-time control of the output of the heating device 112 and substrate-vapor deposition source distance Ts based on the respective vapor deposition rates detected by the thickness monitors 101 and 102, each vapor deposition rate, particularly the vapor deposition rate (second vapor deposition rate) on the substrate 130 can be controlled with high precision, so that a vapor deposition film, preferably an organic film, that has the desired thickness can be formed on the substrate 130.

Also, since the control of the second vapor deposition rate by the second control system shows very high response performance, a change in the first vapor deposition rate which cannot be responded by the first control system in time can be complementarily controlled by the second control system. For example, the first vapor deposition rate may be controlled by the first control system as in the conventional systems, and the control range of the first vapor deposition rate which cannot be adjusted by the first control system may be finely adjusted (corrected) by the second control system. More specifically, the first control system that controls the output of the heating device 112 alone can control the first vapor deposition rate to about the target rate ±3%, and thus the range of the second vapor deposition rate controllable by the second control system that controls the substrate-vapor deposition source distance Ts can be set to the range of about the target rate ±3%. Although it depends on the specific mechanism of the vapor deposition apparatus 100, such a control range corresponds to several millimeters in terms of the up and down movement of the ejection portion 141. Since the amount of the up and down movement is small as described above, the influence of the movement on the thickness distribution of the vapor deposition film to be formed on the substrate 130 can be substantially ignored.

Also, a change in the substrate-vapor deposition source distance Ts enables a uniform change in the vapor deposition rate on the substrate 130 in the entire region in which vapor deposition has been performed (vapor deposition region). Hence, differently from the film formation apparatus described in Patent Literature 1, even when the present embodiment is applied to the scanning vapor deposition apparatus, occurrence of uneven film thickness of the vapor deposition film in the substrate plane can be suppressed. Also, even when the present embodiment is applied to a point source vapor deposition apparatus and vapor co-deposition is performed, the ratio of the vapor deposition rates of multiple materials on the substrates 130 can be controlled with high precision.

The purpose of the thickness monitor 101 is to measure the first vapor deposition rate, i.e., the vapor deposition rate of the vapor deposition particles ejected from the ejection portion 141. If the distance between the thickness monitor 101 and the ejection portion 141 is changed during vapor deposition, the change affects the measurement rate from the thickness monitor 101. Therefore, in order to control the first vapor deposition rate with high precision, the positional relation (within the chain line) between the vapor deposition source 110 and the thickness monitor 101 during vapor deposition is preferably always constant without any change. From this viewpoint, the thickness monitor 101 is preferably fixed to the vapor deposition source lifting mechanism 122.

The purpose of the thickness monitor 102 is to measure the second vapor deposition rate, i.e., the vapor deposition rate on the substrate 130. If the distance between the thickness monitor 102 and the substrate 130 is changed during vapor deposition, the change in the substrate-vapor deposition source distance Ts is not correctly reflected on the measurement rate from the thickness monitor 102. Therefore, in order to control the second vapor deposition rate with high precision, the positional relation (within the dashed line) between the substrate 130 and the thickness monitor 102 during vapor deposition is preferably always constant without any change. From this viewpoint, the vapor deposition monitor 102 is preferably fixed to the vapor deposition unit 170.

The substrate-vapor deposition source distance Ts may be the shortest distance between the ejection portion 141 and the vapor deposition target surface 131 of the substrate 130. In other words, the substrate-vapor deposition source distance Ts may be the distance between the ejection portion 141 and the foot of a perpendicular line drawn from the ejection portion 141 to the vapor deposition target surface 131.

As described above, the vapor deposition apparatus 100 of the present embodiment is configured to form a film on the substrate 130, includes the thickness monitor 102 and the vapor deposition unit 170 provided with the vapor deposition source 110, and is configured to perform vapor deposition while controlling, based on the measurement result from the thickness monitor 102, the distance (substrate-vapor deposition source distance) Ts between the portion (ejection portion) 141 of the vapor deposition source 110 from which the vaporized material is ejected and the surface (vapor deposition target surface) 131 of the substrate 130 on which vapor deposition is performed. By controlling the substrate-vapor deposition source distance Ts, the density of vapor deposition particles on the vapor deposition target surface 131 can be controlled. Therefore, since vapor deposition can be performed while the substrate-vapor deposition source distance Ts is controlled based on the detection result from the thickness monitor 102, feedback control with a small time constant and very high response performance can be achieved. Accordingly, the vapor deposition rate (second vapor deposition rate) on the substrate 130 can be controlled with high precision. Also, since vapor deposition is performed while the substrate-vapor deposition source distance Ts is controlled, the vapor deposition rate on the substrate 130 can be changed in the entire vapor deposition region.

The change range of the substrate-vapor deposition source distance Ts is not particularly limited, and can be appropriately set depending on the restrictions such as the acceptable characteristics of the vapor deposition film. When Ts is changed, a change in the density distribution of vapor deposition particles on the substrate 130 is unavoidable. However, the change in the density distribution occurs not locally but in the entire vapor deposition region. Also, in the present embodiment, the vapor deposition rate on the substrate 130 can be controlled with high precision in the entire vapor deposition region as described above. Therefore, the vapor deposition apparatus 100 of the present embodiment configured to control Ts can reduce the change in the thickness distribution of the vapor deposition film compared to the film formation apparatus described in Patent Literature 1 which adjusts the scattering range.

The vapor deposition apparatus 100 of the present embodiment also includes the vapor deposition source moving mechanism 120 which is configured to move the vapor deposition source 110 to change the height of the portion (ejection portion) 141 from which the vaporized material is ejected. This structure is preferred when the present embodiment is applied to an in-line vapor deposition apparatus, particularly to an in-line vapor deposition apparatus including multiple vapor deposition sources and a transfer mechanism disposed above all of the vapor deposition sources. This is because since it is not easy to lift up or down the substrate 130 at some points of the transfer route for the substrate 130, it will be easier to lift up or down the vapor deposition source corresponding to any of the points.

The present embodiment may be applied to a cluster vapor deposition apparatus including a transfer mechanism configured to move the vapor deposition source 110, not the substrate 130, in the transfer direction. In this case, the vapor deposition apparatus 100 preferably includes a substrate moving mechanism which changes the height of the substrate 130. This is because if the transfer mechanism configured to move the vapor deposition source 110 and the vapor deposition source moving mechanism are arranged in the vicinity of the vapor deposition source 110 in such a cluster vapor deposition apparatus, the arrangement leads to a complicated design, which may require a large space around the vapor deposition source 110 or cause a problem of vibration when the vapor deposition source 110 is transferred.

In the case that the vapor deposition apparatus 100 includes a substrate moving mechanism, the thickness monitor 101 is preferably fixed to the vapor deposition unit 170, the substrate moving mechanism preferably includes the motor driving device and the substrate lifting mechanism, and the thickness monitor 102 is preferably fixed to the substrate lifting mechanism. Here, the motor driving device is configured to convert a height control signal input from the control device 103 into a drive current for the substrate lifting mechanism to be driven, and supplies the drive current to the substrate lifting mechanism. The substrate lifting mechanism is configured to convert the drive current supplied by the motor driving device to a mechanical work (mechanical energy). The substrate lifting mechanism is connected to the substrate holder 104, and moves the substrate holder 104 up and down, i.e., lifts it up and down, to change the height of the substrate 130.

The vapor deposition source 110 includes the heating device 112. The vapor deposition apparatus 100 of the present embodiment includes the thickness monitor 101, and is configured to perform vapor deposition while controlling the output of the heating device 112 based on the detection result from the thickness monitor 101. Thereby, the vapor deposition rate on the substrate 130 can be controlled not only by adjusting the substrate-vapor deposition source distance Ts but also by adjusting the output of the heating device 112, so that the amount of change in the substrate-vapor deposition source distance Ts can be reduced. Accordingly, the influence of the change in the substrate-vapor deposition source distance Ts on the thickness distribution of the vapor deposition film can be very small.

The substrate-vapor deposition source distance Ts may be controlled by proportional control or PID control. Thereby, the second vapor deposition rate can be controlled with higher precision.

The output of the heating apparatus 112 may be controlled by PID control. Thereby, the first vapor deposition rate can be controlled with higher precision.

Furthermore, the vapor deposition source 110 may include the crucible 111 provided with the opening 115, and the portion (ejection portion) 141 from which the vaporized material is ejected may be the opening 115. Thereby, in the vapor deposition apparatus using a crucible as the vapor deposition source, the vapor deposition rate on the substrate 130 in the entire vapor deposition region can be controlled with high precision.

The present embodiment is substantially the same as Embodiment 1 except that the feedback control by the first control system is not performed. Therefore, in the present embodiment, the features unique to the present embodiment are mainly described, and the same features as in Embodiment 1 are not described. The components having the same or similar function in the present embodiment and Embodiment 1 are represented with the same reference numeral.

In the present embodiment, from the viewpoint of considerably reducing the cost, the feedback control by the first control system is not performed, and the output of the heating device 120 is fixed at a predetermined value. Also in this case, similarly to Embodiment 1, the vapor deposition rate on the substrate 130 can be controlled with high precision by the second control system in the entire vapor deposition region. However, if the second vapor deposition rate which is much higher than the range of the target rate ±3% is corrected only by the second control system, the change in the thickness distribution of the vapor deposition film may be large. Accordingly, from the viewpoint of effectively suppressing the change in the thickness distribution of the vapor deposition film, the first and second control systems are preferably used in combination as in Embodiment 1.

The present embodiment is substantially the same as Embodiment 1 except that one of the thickness monitors 101 and 102 is not used. Therefore, in the present embodiment, the features unique to the present embodiment are mainly described, and the same features as in Embodiment 1 are not described. The components having the same or similar function in the present embodiment and Embodiment 1 are represented with the same reference numeral.

In the present embodiment, although the control precision decreases, vapor deposition is performed while the substrate-vapor deposition source distance Ts and the output of the heating device 112 are controlled based on the measurement results from the thickness monitor 101 or 102, from the viewpoint of suppressing the cost.

For example, the thickness monitor 101 may not be used, and the thickness monitor 102 may be used alone. In this case, the thickness monitor 102 corresponds to the first thickness monitor of the vapor deposition apparatus of the present invention. The thickness monitor 102 alone can be used without the thickness monitor 101 because the change in the first vapor deposition rate when the distance between the ejection portion 141 and the thickness monitor 102 is changed can be roughly calculated, and the information on the distance is already known as a control parameter. Therefore, even when the thickness monitor 101 is not used, the first vapor deposition rate can be separated (estimated) from the second vapor deposition rate measured by the thickness monitor 102, and the output of the heating device 112 can be controlled based on the separated (estimated) first vapor deposition rate. Here, a method of more surely estimating the first vapor deposition rate may be employed which includes measuring the first vapor deposition rate and the second vapor deposition rate when the distance between the ejection portion 141 and the thickness monitor 102 is changed, forming a calibration curve based on the measurement results, and calculating the first vapor deposition rate based on the calibration curve.

In an opposite manner, the thickness monitor 101 may be used alone without the thickness monitor 102. In this case, the thickness monitor 101 corresponds to the first thickness monitor of the vapor deposition apparatus of the present invention. The thickness monitor 102 alone can be used without the thickness monitor 101 because the change in the second vapor deposition rate when the substrate-vapor deposition source distance Ts is changed can be calculated, and the information on the substrate-vapor deposition source distance Ts is already known as a control parameter. Therefore, even when the thickness monitor 102 is not used, the second vapor deposition rate can be separated (calculated) from the first vapor deposition rate measured by the thickness monitor 101, and the substrate-vapor deposition source distance Ts can be controlled based on the separated (calculated) second vapor deposition rate. Here, a method of more surely estimating the second vapor deposition rate may be employed which includes measuring the behavior of the change in the second vapor deposition rate when the substrate-vapor deposition source distance Ts is changed, forming a calibration curve based on the measurement results, and calculating the second vapor deposition rate based on the calibration curve.

The present embodiment is substantially the same as Embodiment 1 except that the control system is different. Therefore, in the present embodiment, the features unique to the present embodiment are mainly described, and the same features as in Embodiment 1 are not described. The components having the same or similar function in the present embodiment and Embodiment 1 are represented with the same reference numeral. However, in the present embodiment, the thickness monitor 101 corresponds to the first thickness monitor of the vapor deposition apparatus of the present invention, and the thickness monitor 102 corresponds to the second thickness monitor of the vapor deposition apparatus of the present invention. In the present embodiment, the thickness monitor 101 corresponding to the first thickness monitor is preferably fixed to the vapor deposition source moving mechanism 120, and the thickness monitor 102 corresponding to the second thickness monitor is preferably fixed to the vapor deposition unit 170.

FIG. 8 is a schematic view for explaining a control system of a vapor deposition apparatus of Embodiment 4. FIG. 9 is a view schematically illustrating one example of changes with time in the vapor deposition rate and a substrate-vapor deposition source distance Ts in Embodiment 4.

The vapor deposition apparatus of the present embodiment includes a control system as illustrated in FIG. 8. That is, based on the measurement result of the thickness monitor 101, the substrate-vapor deposition source distance Ts and the output of the heating device 112 are controlled, and the proportionality coefficient in control of the substrate-vapor deposition source distance Ts is controlled based on the measurement result from the thickness monitor 102. Correct control in the control system including the thickness monitor 101 gives a desired constant vapor deposition rate which is measured by the thickness monitor 102. In contrast, in the case that the correlation between the substrate-vapor deposition source distance Ts and the vapor deposition rate measured by the thickness monitor 102 is not correct, as shown in FIG. 9, the vapor deposition rate measured by the thickness monitor 102 changes to follow the change in the substrate-vapor deposition source distance Ts. That is, when the target rate is R0, a vapor deposition rate measured by the thickness monitor 102 is R1, and the substrate-vapor deposition source distance when this vapor deposition rate is measured by the thickness monitor 102 is Ts1, the amount of operation, namely the output (Ts2) of the substrate-vapor deposition source distance is defined as follows.

Ts2=K0×√(R1/R0)×Ts1+K1

Here, usually, K0 is 1 and K1 is 0.

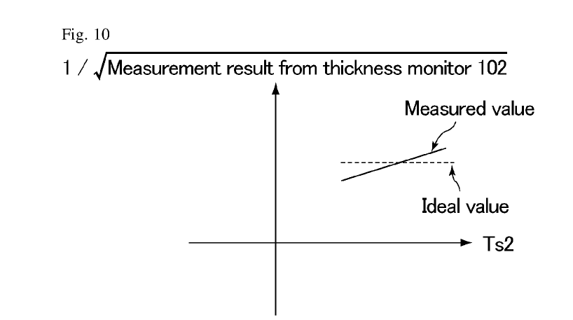

FIG. 10 is a view schematically illustrating the relation between the output value of the substrate-vapor deposition source distance and the measurement results from the thickness monitor in Embodiment 4.

As illustrated in FIG. 10, when Ts2 and 1/√(measurement result from thickness monitor 102) over a certain period of time are plotted and the first and second control rates are controlled correctly, the vapor deposition rate measured by the thickness monitor 102 becomes flat independently of Ts2 (dashed line in FIG. 10). However, in the case that the measured values change depending on Ts2 as illustrated in FIG. 10, the measured values are fitted to the above formula to determine K0 and K1, and the substrate-vapor deposition source distance Ts can be corrected based on the determined K0 and K1.

The vapor deposition apparatus of the present embodiment can be simplified compared with that of Embodiment 1. A thickness monitor utilizing a quartz resonator is suitable as each of the thickness monitors 101 and 102. However, if a certain amount or more of vapor deposition particles adhere to the quartz resonator, measurement errors arise. Hence, thickness monitors utilizing a quartz resonator require an appropriate change of the quartz resonator to a new one. Therefore, the vapor deposition apparatus of Embodiment 1 preferably includes thickness monitors each utilizing multiple quartz resonators as the thickness monitors 101 and 102 such that the quartz resonators can be changed to new ones as needed. In contrast, in the present embodiment, the thickness monitor 102 does not need to always measure the vapor deposition rate, and can measure the vapor deposition rate constantly enough to determine the proportionality coefficient, over any period of time. Therefore, in the present embodiment, a simple thickness monitor can be used as the thickness monitor 102.

Here, the direction of the components of the vapor deposition apparatus of each embodiment is not particularly limited. For example, all the components described above may be arranged upside down, or the substrate 130 may be placed vertically and the vapor deposition stream 140 may be sprayed to the substrate 130 from the side (lateral direction).

The organic EL display device produced by the vapor deposition apparatus of each embodiment may be a monochrome display device, and each pixel may not be divided into sub-pixels. In this case, in a light-emitting layer vapor deposition step, vapor deposition of luminescent material(s) of one color may be performed to form light-emitting layers of only one color.

Also in vapor deposition steps other than the light-emitting layer vapor deposition step, a thin film may be patterned by the same procedure as in the light-emitting layer vapor deposition step. For example, an electron transport layer may be formed for sub-pixels of each color.

Furthermore, the embodiments each have been described with an example that the organic layers of the organic EL elements are formed. However, the vapor deposition apparatus of the present invention can be used not only for production of organic EL elements but also for formation of various pattered thin films.

Hereinafter, Examples 1 to 3 according to Embodiment 1 are described.

In Examples 1 to 3, as illustrated in FIG. 6, the feedback control was performed by each of the first and second control systems.

### Example 1

In the present example, vapor deposition was performed while the substrate (film formation target substrate) was scanned (transferred) relatively to a fixed separately coloring mask using a scanning vapor deposition apparatus.

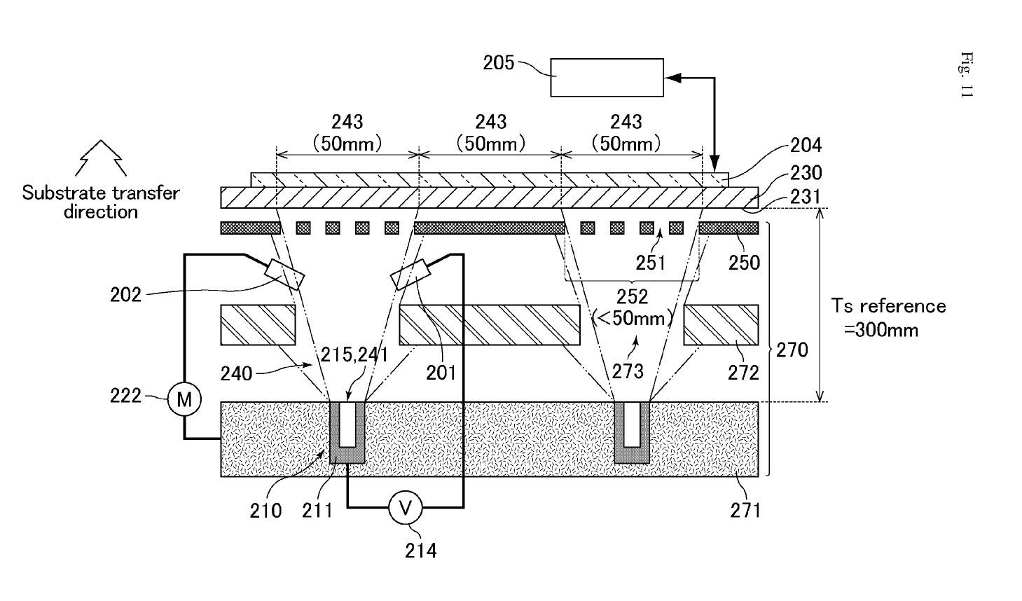

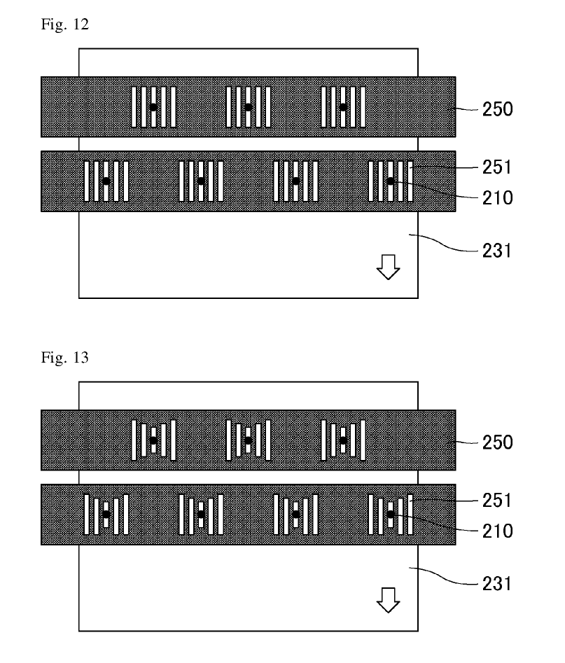

FIG. 11 is a schematic view illustrating the basic structure of a vapor deposition apparatus of Example 1. FIG. 12 is a schematic plan view of the vapor deposition apparatus of Example 1.

As illustrated in FIGS. 11 and 12, the vapor deposition apparatus of the present example includes a vapor deposition unit 270. The vapor deposition unit 270 includes two masks 250, vapor deposition sources 210 each including a crucible 211, a heater (not illustrated), and a heating power supply 214, a crucible supporting material 271 that supports the crucibles 211, and a limiting component 272. The vapor deposition sources 210 are disposed in a staggered pattern.

The limiting component 272 is a plate component that is provided with openings 273 formed in a staggered pattern correspondingly to openings 215 of the crucibles 211, and is designed to remove unnecessary components from the vapor deposition particles ejected from the openings 215 of the crucibles 211. To each opening 273 rises a vapor deposition stream 240 from the corresponding opening 215 therebelow. Some of the vapor deposition particles contained in the vapor deposition stream 240 can pass through the opening 273 to reach one of the masks 250. The other vapor deposition particles adhere to the limiting component 272 and cannot pass through the opening 273, failing to reach any of the masks 250. In this manner, the limiting component 272 controls the vapor deposition streams 240 which spread isotropically immediately after ejected from the respective openings 215, shutting out poorly directive components to obtain highly directive components. Also, the limiting component 272 prevents each vapor deposition stream 240 from passing through the openings 273 other than the corresponding opening 273 positioned directly above the stream.

Also, each mask 250 is provided with mask open regions 252 correspondingly to the vapor deposition streams 240. The mask open regions 252 are arranged in the staggered pattern correspondingly to the vapor deposition sources 210 (the openings 215 of the crucibles 211) and the multiple openings 273. The mask open regions 252 of each mask 250 are arranged at the same pitch as the corresponding crucibles 211 and the corresponding openings 273. In each mask open region 252, openings 251 are formed. As a result, some of the vapor deposition particles having reached one of the masks 250 can pass through the openings 251, and can accumulate on the substrate 230 in the pattern corresponding to the openings 251. All the openings 251 have a rectangular shape having the same length.

FIG. 13 is a schematic plan view of an alternative example of the vapor deposition apparatus of Example 1.

As illustrated in FIG. 13, in each mask open region 252, an opening 251 positioned farther from the vapor deposition source 210 below may have a longer length.

The vapor deposition apparatus of the present embodiment further includes the substrate holder 204 and a transfer mechanism 205.

The substrate holder 204 is a component configured to hold the substrate 230 such that the vapor deposition target surface 231 of the substrate 230 faces the masks 250. The substrate holder 204 is preferably an electrostatic chuck.

The transfer mechanism 205 is connected to the substrate holder 204, and can move the substrate 230 held by the substrate holder 204 at a constant speed in the transfer direction perpendicular to the normal direction of the substrate 230 (direction from the paper surface of FIG. 11 toward the depth side). The vapor deposition apparatus of the present example is configured to perform vapor deposition while scanning the substrate 230.

The transfer mechanism 205 includes, for example, a linear guide, a ball screw, a motor connected to the ball screw, and a motor driving control portion connected to the motor, and integrally moves the substrate holder 204 and the substrate 230 by driving the motor using the motor driving control portion.

The transfer mechanism 205 may be any one that can move at least one of the substrate 230 and the vapor deposition unit 270 relatively to the other. Hence, the substrate 230 may be fixed and the vapor deposition unit 270 may be moved by the transfer mechanism 205, or both of the substrate 230 and the vapor deposition unit 270 may be moved by the transfer mechanism 205.

The vapor deposition apparatus of the present example further includes thickness monitors 201 and 202, a control device (not illustrated), a motor driving device (not illustrated), and a drive motor 222 connected to the crucible supporting material 271.

In the present example, the thickness monitor 201 corresponds to the second thickness monitor of the vapor deposition apparatus of the present invention, and the thickness monitor 202 corresponds to the first thickness monitor of the vapor deposition apparatus of the present invention.

The sensor portion of each of the thickness monitors 201 and 202 is disposed in a region that is between the limiting component 272 and the masks 250 and can come into contact with one vapor deposition stream 240. The thickness monitor 201, the control device, the heater, and the heating power supply 214 constitute the first control system, and the thickness monitor 202, the control device, the motor driving device, and the drive motor 222 constitute the second control system.

In the present example, the first and second vapor deposition rates were respectively measured by the thickness monitors 201 and 202, and vapor deposition was performed while the first and second control systems performed the feedback control respectively to control the first and second vapor deposition rates.

The height of the ejection portion 241 from which a vaporized material was ejected was adjusted by moving the crucible supporting material 271 up and down to uniformly change the heights of the openings 215 of the crucibles 211.

The reference distance (Ts reference) for the distance between the ejection portion 241 and the vapor deposition target surface 231 of the substrate 230, i.e., the substrate-vapor deposition source distance (Ts) was set to 300 mm. The amount of change in the substrate-vapor deposition source distance Ts was set to Ts reference ±5 mm. The pitch of change for the substrate-vapor deposition source distance Ts was set to 0.1 mm. The width of each vapor deposition region 243 on the substrate 230 on which one vapor deposition source 210 performs vapor deposition was 50 mm. The distance between the adjacent vapor deposition regions 243 was also 50 mm. The gap between the substrate 230 and each of the masks 250 was 1 mm. A mask open region 252 was formed correspondingly to each vapor deposition region 243. The width of each mask open region 252 was set to 49.83333 mm from the following formula.

Width of mask open region=((L reference/Ts reference)×(Ts reference−gap))×2

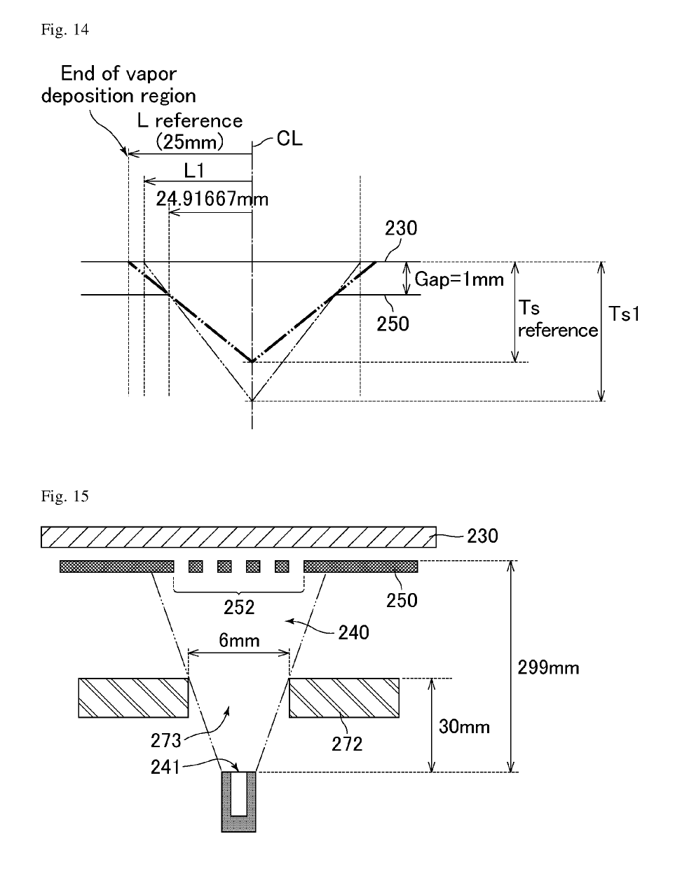

The L reference in the formula is described later with reference to FIG. 14.

The pitch of change for the substrate-vapor deposition source distance Ts is not particularly limited, and may be appropriately set. The substrate-vapor deposition source distance Ts may not be changed stepwise as described above but may be changed linearly (continuously).

### (Influence of Ts Change on Vapor Deposition Rate)

The density of vapor deposition particles when Ts is changed is inversely proportional to the square of Ts. Hence, if the substrate-vapor deposition source distance at Ts=305 mm was set to Ts1 and the substrate-vapor deposition source distance at Ts=295 mm was set to Ts2, the ratio of the vapor deposition rate (R1 or R2) at Ts1 or Ts2 to the vapor deposition rate (R reference) at the Ts reference can be determined from one of the following formulas.

R1/R reference=300²/305²=0.967

R2/R reference=300²/295²=1.034

Hence, in the present example, changing Ts in the range of Ts reference ±5 mm enables a change of the vapor deposition rate in the range of about the target rate ±3%.

### (Influence of Ts Change on Position Shift in Patterning)

FIG. 14 is a schematic view for explaining the change in pattern when Ts is changed in Example 1.

The openings 251 of each mask 250 are designed such that films are formed at the desired positions on the substrate 230. However, when the crucibles 211 are lifted up or down, as illustrated in FIG. 14, Ts is changed, and thus the angles of incidence of the vapor deposition particles to the mask 250 are changed, whereby the patterning positions are shifted. In particular, the patterning position for a film formed by the opening 251 that is positioned at the end of the vapor deposition region 243 and at the end of the mask open region 252 is changed most. In the following, the result of calculating the position shift for the patterning position is shown. The opening 251 at the end of the mask open region 252 is at a position shifted by 24.91667 mm from the center line CL that passes through the center of the opening 215 of the crucible 211. Here, the patterning positions (distances from the center line CL to the patterning positions) at the end of the vapor deposition region 243 at the Ts reference and Ts1 are respectively defined as L reference and L1. Then, the amount of the position shift (L1−L reference) between the patterning positions at the Ts reference and at Ts1 can be determined from the following formula.

L1−L=(24.91667/(305−1))×305)−((24.91667/(300−1))×300)=−0.00137 mm

As shown above, in the present example, the maximum amount of position shift for the patterning positions at the Ts reference and at the Ts reference ±5 mm is about 1.4 μm. Such an amount of position shift would not raise any problem.

Here, if such an amount of position shift raises a problem, the masks 250 may be lifted up or down simultaneously with lifting up or down of the crucibles 211, which enables correction of the position shift of the patterning. For example, if the gap after correction at Ts=Ts1 (=305 mm) is set to Gap1, Gap1 can be calculated from the following formula.

Gap1=305−(305/25)×L1

### (Influence of Ts Change on Vapor Deposition Region)

FIG. 15 is a schematic view for explaining the influence of a change in Ts on the vapor deposition region in Example 1.

As illustrated in FIG. 15, in Example 1, the distance between the ejection portion 241 and the upper surface (surface on the substrate 230 side) of the limiting component 272 was set to 30 mm, and the width of the openings 273 of the limiting component 272 was set to 6 mm. Since the amount of change of Ts is the Ts reference ±5 mm, a change in Ts causes the width of the vapor deposition stream 240 on the lower surface of each mask 250 (surface on the limiting component 272 side) to be changed by the range of 52.11429 mm to 70.56 mm. However, since a sufficient margin for the width (=49.83333 mm) of the mask open region 252 can be obtained, a change in Ts does not have an influence on the vapor deposition region.

Here, the width of the openings 273 of the limiting component 272 can be appropriately set, but too large a width may allow unnecessary vapor deposition particles to reach the mask open regions 252 through the adjacent openings 273 of the corresponding opening 273, due to a phenomenon such as scattering of vapor deposition particles. That is, surrounding of vapor deposition particles may occur. Therefore, from the viewpoint of suppressing surrounding of vapor deposition particles, the width of the openings 273 of the limiting component 272 is preferably set within 6 mm+1 mm.

Although the limiting component 272 was fixed and only the crucible supporting material 271 was moved up and down in the present example, the limiting component 272 may be moved up and down to be synchronized with the up and down movement of the crucible supporting material 271. Thereby, the range (angle) of the vapor deposition streams 240 having passed through the limiting component 272 can be prevented from changing, and the openings 273 of the limiting component 272 can be made small. In particular, it is preferred to move the limiting component 272 up and down such that the width of the vapor deposition streams 240 on the lower surface (surface on the limiting component 272 side) of each mask 250 would not be changed. Thereby, the openings 273 can be minimized, so that the occurrence of surrounding of vapor deposition particles can be minimized.

(Influence of Ts Change on in-Plane Film Thickness Distribution)

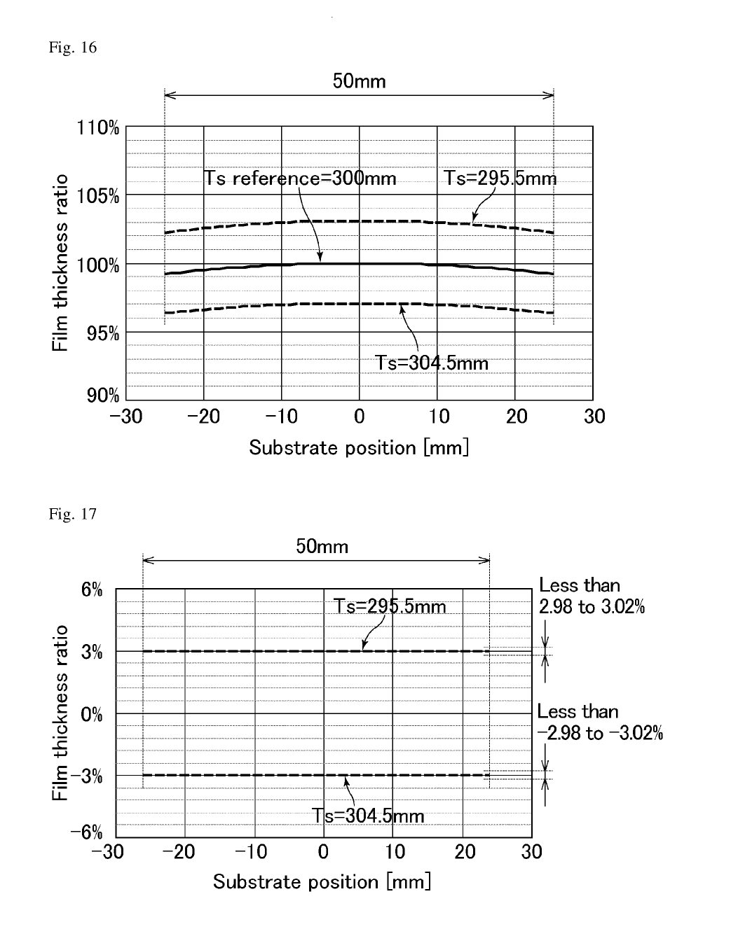

FIG. 16 is a graph showing the relation between Ts and a thickness distribution of a vapor deposition film in Example 1. FIG. 16 illustrates the results of calculation with N value=2.3.

Since the interference between vapor deposition sources is small in scanning vapor deposition apparatuses, the vapor deposition sources of the scanning vapor deposition apparatuses have the same properties as point vapor deposition sources in terms of the distribution of film thickness. However, since the width of the vapor deposition regions is as small as 50 mm compared with the Ts reference which is 300 mm, the influence of a Ts change on the thickness distribution is small as shown in FIG. 16.

FIG. 17 is a graph showing each change ratio of the film thickness obtained at adjusted Ts to that obtained at Ts reference in Example 1. The values in FIG. 17 were calculated from the results shown in FIG. 16.

As shown in FIG. 17, even when the Ts alone was changed under the same conditions except for Ts, a change in the thickness distribution at the adjusted Ts from that at the Ts reference was less than ±0.02%, which is very small. Therefore, the influence of adjustment of Ts on the thickness distribution does not appear on the values, which means that there is substantially no influence.

### (Control of Vapor Deposition Rate by Ts Change)

In the present example, the vapor deposition rate on the substrate 230 was controlled at a pitch of 0.07% in the range of about ±3% of the vapor deposition rate on the substrate 230 at the Ts reference. In this manner, in the present example, adjustment of the height of the ejection portion 241 and adjustment of the heating temperature of the material in combination led to the precise vapor deposition rate of ±0.07% or less on the substrate 230.

Also, the vapor deposition apparatus of the present example includes the transfer mechanism 205 configured to move at least one of the substrate 230 and the vapor deposition sources 210 relatively to the other in the direction perpendicular to the normal direction of the substrate 230. Therefore, in the present example, the scanning vapor deposition apparatus can control the vapor deposition rate on the substrate 230 with high precision, and unevenness of the thickness distribution of the vapor deposition film can be suppressed. In the scanning vapor deposition apparatus, in particular, variation in vapor deposition rate on the substrate 230 directly leads to variation in thickness. Hence, the present example enables effective suppression of uneven thickness distribution of the vapor deposition film.

Furthermore, the vapor deposition apparatus of the present example includes the vapor deposition unit 270 provided with the vapor deposition sources 210 and the masks 250, and the transfer mechanism 205 is configured to move at least one of the substrate 230 and the vapor deposition unit 270 relatively to the other. Therefore, in the present example, since the mask 250 can be made smaller than the substrate 230, the mask 250 can be easily produced, and occurrence of deflection of the mask 250 due to the weight of the mask 250 can be suppressed.

### Example 2

In the present example, vapor deposition was performed while the substrate (film formation target substrate) to which the mask was attached was rotated by the substrate holder with a rotating mechanism.

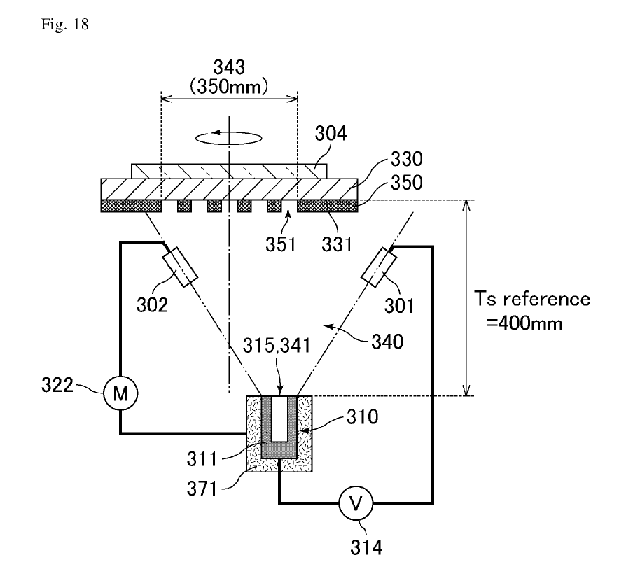

FIG. 18 is a schematic view illustrating the basic structure of a vapor deposition apparatus of Example 2.

As illustrated in FIG. 18, the vapor deposition apparatus of the present example includes a mask 350, a vapor deposition source 310 including a crucible 311, a heater (not illustrated) and a heating power supply 314, a crucible supporting material 371 that supports the crucible 311, and a substrate holder 304 with a rotating mechanism.

The substrate holder 304 is a component configured to hold a substrate 330 such that a vapor deposition target surface 331 of the substrate 330 faces the mask 350. Suitable as the substrate holder 304 is an electrostatic chuck. The substrate 330 and the mask 350 are held by the substrate holder 304 in the state where they are in contact with each other.

The substrate holder 304 includes a rotating mechanism (not illustrated) capable of rotating the substrate 330 and the mask 350 integrally at a constant speed. The vapor deposition apparatus of the present example is configured to perform vapor deposition while rotating the substrate 330 and the mask 350.

The rotating mechanism is connected to the substrate holder 304, and includes, for example, a motor (not illustrated) connected to the substrate holder 304 and a motor driving control portion (not illustrated) connected to the motor. The rotating mechanism drives the motor by the motor driving control portion to rotate the substrate holder 304, the substrate 330, and the mask 350 integrally.

Since multiple openings 351 are formed in the mask 350, some of the vapor deposition particles rising from the opening 315 of the crucible 311 can pass through the openings 351, and can accumulate on the substrate 330 in a pattern corresponding to the openings 351.

The vapor deposition apparatus of the present example includes thickness monitors 301 and 302, a control device (not illustrated), a motor driving device (not illustrated), and a drive motor 322 connected to the crucible supporting material 371.

In the present example, the thickness monitor 301 corresponds to the second thickness monitor of the vapor deposition apparatus of the present invention, and the thickness monitor 302 corresponds to the first thickness monitor of the vapor deposition apparatus of the present invention.

The sensor portion of each of the thickness monitors 301 and 302 is disposed in a region where the sensor portion can come into contact with the vapor deposition stream 340. The thickness monitor 301, the control device, the heater, and the heating power source 314 constitute the first control system, and the thickness monitor 302, the control device, the motor driving device, and the drive motor 322 constitute the second control system.

In the present example, the first and second vapor deposition rates were respectively measured by the thickness monitors 301 and 302, and vapor deposition was performed while the first and second control systems performed the feedback control respectively to control the first and second vapor deposition rates.

The height of the ejection portion 341 from which a vaporized material is ejected was adjusted by moving the crucible supporting material 371 up and down to change the height of the opening 315 of the crucible 311.

The reference distance (Ts reference) for the substrate-vapor deposition source distance (Ts) was set to 400 mm. The amount of change in the substrate-vapor deposition source distance Ts was set to Ts reference ±6 mm. The pitch of change for the substrate-vapor deposition source distance Ts was set to 0.1 mm. The width of the vapor deposition region 343 on the substrate 330 on which one vapor deposition source 310 performs vapor deposition was 350 mm. The substrate 330 and the mask 350 were rotated together in close contact with each other.

The pitch of change for the substrate-vapor deposition source distance Ts is not particularly limited, and may be appropriately set. The substrate-vapor deposition source distance Ts may not be changed stepwise as described above but may be changed linearly (continuously).

### (Influence of Ts Change on Vapor Deposition Rate)

The density of vapor deposition particles when Ts is changed is inversely proportional to the square of Ts. Hence, if the substrate-vapor deposition source distance at Ts=406 mm was set to Ts1 and the substrate-vapor deposition source distance at Ts=394 mm was set to Ts2, the ratio of the vapor deposition rate (R1 or R2) at Ts1 or Ts2 to the vapor deposition rate (R reference) at the Ts reference can be determined from the following formulas.

R1/R reference=400²/406²=0.971

R2/R reference=400²/394²=1.031

Hence, in the present example, changing Ts in the range of Ts reference ±6 mm enables a change of the vapor deposition rate in the range of about the target rate ±3%.

### (Influence of Ts Change on Position Shift in Patterning)

Since the mask 350 is in close contact with the substrate 330, the patterning position does not change even when Ts is changed.

### (Control of Vapor Deposition Rate by Ts Change)

In the present example, the vapor deposition rate on the substrate 330 was controlled at a pitch of 0.05% in the range of about ±3% of the vapor deposition rate on the substrate 330 at the Ts reference. In this manner, in the present example, adjustment of the height of the ejection portion 341 and adjustment of the heating temperature of the material in combination led to the precise vapor deposition rate of ±0.05% or less on the substrate 330.

Also, the vapor deposition apparatus of the present example includes the mask 350 and the substrate holder 304 with a rotating mechanism configured to rotate the substrate 330 to which the mask 305 has been attached. Therefore, the present example enables suppression of position shift in patterning even when Ts is changed.

Furthermore, even when vapor co-deposition is performed, the ratio of the vapor deposition rates of multiple materials on the substrate 330 can be controlled with high precision.

### Example 3

In the present example, vapor deposition was performed while a substrate (film formation target substrate) to which a mask has been attached was scanned (transferred) by an in-line vapor deposition apparatus.

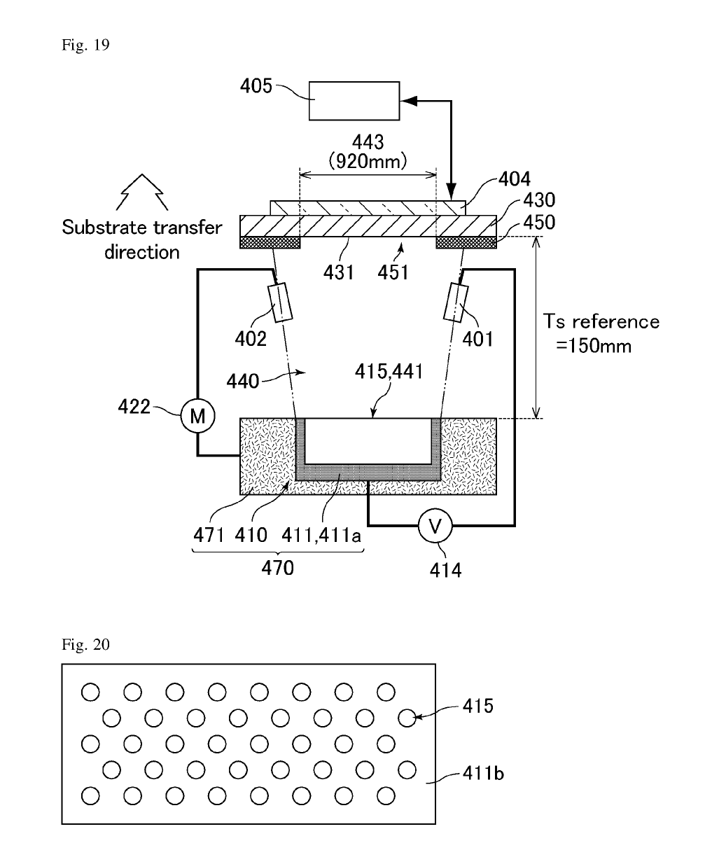

FIG. 19 is a schematic view illustrating the basic structure of a vapor deposition apparatus of Example 3.

As illustrated in FIG. 19, the vapor deposition apparatus of the present example includes a mask 450, a vapor deposition source 410 including a crucible 411, a heater (not illustrated) and a heating power supply 414, a crucible supporting material 471 that supports the crucible 411, a substrate holder 404, and a transfer mechanism 405.

FIG. 20 is a schematic plan view of vapor deposition sources provided to the vapor deposition apparatus of Example 3.

The vapor deposition source 410 is a vapor deposition source with a large width which is called a line source. The crucible 411 includes a vessel 411a designed to house the material, and a cover 411b designed to cover the vessel 411a. As illustrated in FIG. 20, the cover 411b includes multiple nozzles which are distributed throughout the cover 411b. The vaporized material is ejected from openings 415 of the respective nozzles as vapor deposition streams which form one large vapor deposition stream 440.

The substrate holder 404 is a component configured to hold a substrate 430 such that a vapor deposition target surface 431 of the substrate 430 faces the mask 450. Suitable as the substrate holder 404 is an electrostatic chuck. The substrate 430 and the mask 450 are held by the substrate holder 404 in the state where they are in contact with each other.

The transfer mechanism 405 is connected to the substrate holder 404, and can move the substrate 430 held by the substrate holder 404 in the transfer direction perpendicular to the normal direction of the substrate 430 (direction from the paper surface of FIG. 19 toward the depth side). The vapor deposition apparatus of the present example performs the vapor deposition while scanning the substrate 430.

The transfer mechanism 405 includes, for example, a linear guide, a ball screw, a motor connected to the ball screw, and a motor driving control portion connected to the motor, and integrally moves the substrate holder 404 and the substrate 430 by driving the motor using the motor driving control portion.

The transfer mechanism 405 may be any one that can move at least one of the substrate 430 and the vapor deposition unit 470 including the crucible 411, the heater, and the crucible supporting material 471 relatively to the other. Hence, the substrate 430 may be fixed and the vapor deposition unit 470 may be moved by the transfer mechanism 405, or both the substrate 430 and the vapor deposition unit 470 may be moved by the transfer mechanism 405.

Since one large opening 451 is formed in the mask 450, some of the vapor deposition particles having risen from the opening 415 of the crucible 411 and having reached the mask 450 can pass through the opening 451, and can accumulate on the substrate 430 in a pattern corresponding to the opening 451.

The vapor deposition apparatus of the present example further includes thickness monitors 401 and 402, a control device (not illustrated), a motor driving device (not illustrated), and a drive motor 422 connected to the crucible supporting material 471.

In the present example, the thickness monitor 401 corresponds to the second thickness monitor of the vapor deposition apparatus of the present invention, and the thickness monitor 402 corresponds to the first thickness monitor of the vapor deposition apparatus of the present invention.

The sensor portion of each of the thickness monitors 401 and 402 is disposed in a region that can come into contact with the vapor deposition stream 440. The thickness monitor 401, the control device, the heater, and the heating power supply 414 constitute the first control system, and the thickness monitor 402, the control device, the motor driving device, and the drive motor 422 constitute the second control system.

In the present example, the first and second vapor deposition rates were respectively measured by the thickness monitors 401 and 402, and vapor deposition was performed while the first and second control systems performed the feedback control respectively to control the first and second vapor deposition rates.

The height of the ejection portion 441 from which a vaporized material was ejected was adjusted by moving the crucible supporting material 471 up and down to change the height of the opening 415 of the crucible 411.

The reference distance (Ts reference) of the substrate-vapor deposition source distance (Ts) was set to 150 mm. The amount of change in the substrate-vapor deposition source distance Ts was set to Ts reference ±3 mm. The pitch for the substrate-vapor deposition source distance Ts was set to 0.1 mm. The width of the vapor deposition region 443 on the substrate 430 on which one vapor deposition source 410 performs vapor deposition was 920 mm. The substrate 430 and the mask 450 were transferred together in close contact with each other.

The pitch of change for the substrate-vapor deposition source distance Ts is not particularly limited, and may be appropriately set. The substrate-vapor deposition source distance Ts may not be changed stepwise as described above but may be changed linearly (continuously).

### (Influence of Ts Change on Vapor Deposition Rate)

The density of vapor deposition particles when Ts is changed is inversely proportional to the square of Ts. Hence, if the substrate-vapor deposition source distance at Ts=153 mm was set to Ts1 and the substrate-vapor deposition source distance at Ts=147 mm was set to Ts2, the ratio of the vapor deposition rate (R1 or R2) at Ts1 or Ts2 to the vapor deposition rate (R reference) at the Ts reference can be determined from the following formulas.

R1/R reference=150²/153²=0.961

R2/R reference=150²/147²=1.041

Hence, in the present example, changing Ts in the range of Ts reference ±3 mm enables a change of the vapor deposition rate in the range of about the target rate ±4% on the substrate 430.

### (Influence of Ts Change on Position Shift in Patterning)

Since the mask 450 is in close contact with the substrate 430, the patterning position does not change even when Ts is changed.

(Influence of Ts Change on in-Plane Thickness Distribution)

Since what is called a line source was used in the present example, the range of the vapor deposition stream 440 reaching the substrate is hardly changed even when Ts is changed.

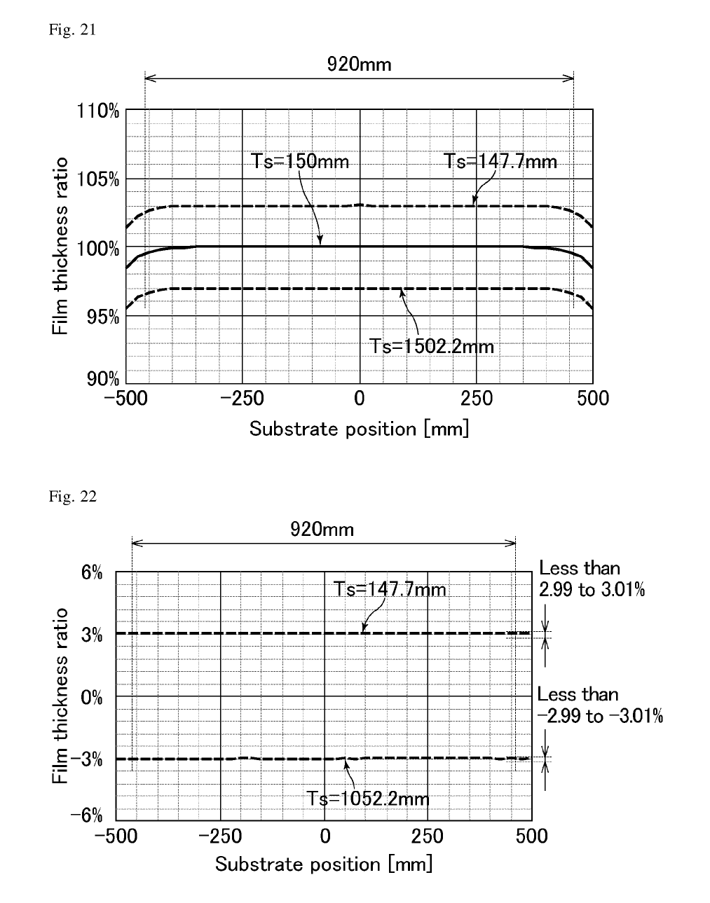

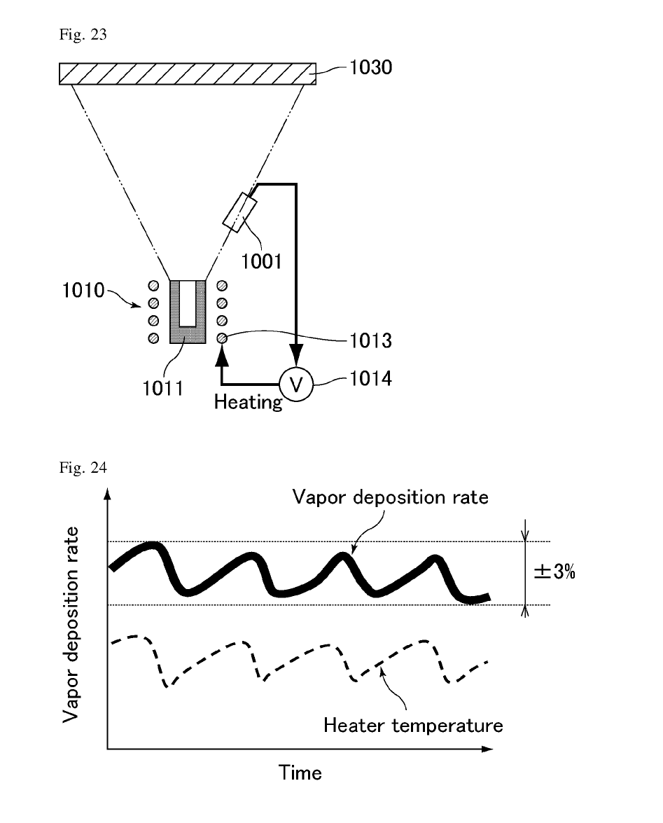

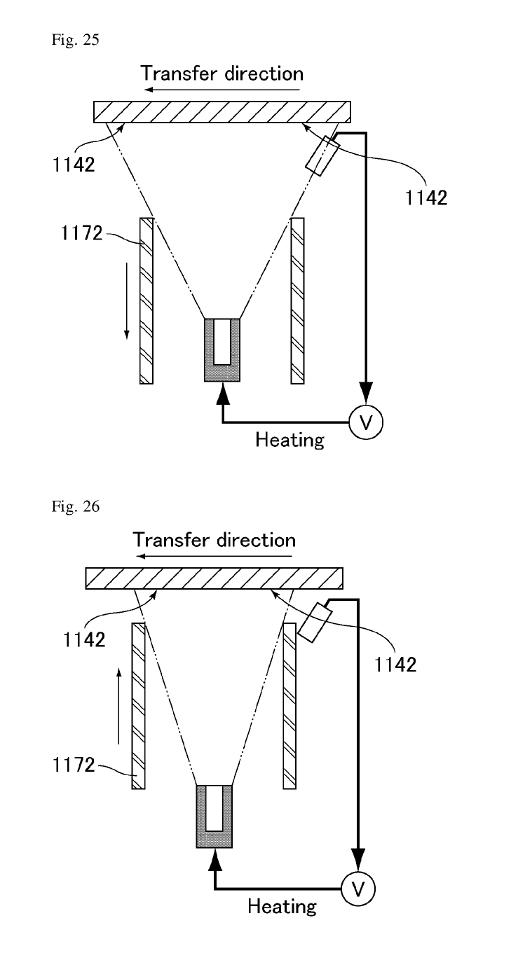

FIG. 21 is a graph showing the relation between Ts and a thickness distribution of the vapor deposition film in Example 3.

FIG. 21 illustrates the results of calculation with N value of each nozzle=8. With N value=8, a graph showing a thickness distribution similar to the thickness distribution actually obtained when vapor deposition is performed using a line source was obtained. The N value of each nozzle is considered to have been relatively large as described above because a line source causes interference between the vapor deposition streams ejected from adjacent nozzles to bring the scattering direction of the vapor deposition particles closer to the direction right above the crucible 411. However, since the nozzles are uniformly distributed throughout the cover 411b, the influence of Ts change on the thickness distribution is small as shown in FIG. 21.

FIG. 22 is a graph showing each change ratio of the film thickness obtained at adjusted Ts to that obtained at Ts reference in Example 3. The values in FIG. 22 were calculated from the results shown in FIG. 21.

As shown in FIG. 22, even when the Ts alone was changed under the same conditions except for Ts, a change in the thickness distribution at the adjusted Ts from that at the Ts reference was less than ±0.01%, which is very small. Therefore, the influence of adjustment of Ts on the thickness distribution does not appear on the values, which means that there is substantially no influence.

### (Control of Vapor Deposition Rate by Ts Change)

In the present example, the vapor deposition rate on the substrate 430 was controlled at a pitch of 0.13% in the range of about ±4% of the vapor deposition rate on the substrate 430 at the Ts reference. In this manner, in the present example, adjustment of the height of the ejection portion 441 and adjustment of the heating temperature of the material in combination led to the precise vapor deposition rate of ±0.13% or less on the substrate 430.

Also, the vapor deposition apparatus of the present example includes the transfer mechanism 405 configured to move at least one of the substrate 430 and the vapor deposition source 410 relatively to the other in the direction perpendicular to the normal direction of the substrate 430. Therefore, in the present example, the scanning vapor deposition apparatus can control the vapor deposition rate on the substrate 430 with high precision, and unevenness of the thickness distribution of the vapor deposition film can be suppressed. In the scanning vapor deposition apparatus, in particular, variation in vapor deposition rate on the substrate 430 directly leads to variation in thickness. Hence, the present example enables effective suppression of uneven thickness distribution of the vapor deposition film.

Furthermore, the vapor deposition apparatus of the present example includes the mask 450, and the transfer mechanism 405 is configured to move at least one of the vapor deposition source 410 and the substrate 430 to which the mask 450 is attached, relatively to the other. Therefore, the present example enables suppression of position shift in patterning even when Ts is changed.

The embodiments described above may be appropriately combined within the spirit of the present invention. Alternative examples of each embodiment may be combined with any of the other embodiments.

### REFERENCE SIGNS LIST

1: organic EL display
2: pixel
2R, 2G, 2B: sub pixel
10: TFT substrate
11: insulating substrate
12: TFT
13: interlayer film
13a: contact hole
14: conductive line
15: edge cover
15R, 15G, 15B: opening
20: organic EL element
21: first electrode
22: hole injection/hole transport layer (organic layer)
23R, 23G, 23B: light-emitting layer (organic layer)
24: electron transport layer (organic layer)
25: electron injection layer (organic layer)
26: second electrode
30: adhesive layer
40: sealing substrate
100: vapor deposition apparatus
101, 102, 201, 202, 301, 302, 401, 402: thickness monitor
103: control device
104, 204, 304, 404: substrate holder
110, 210, 310, 410: vapor deposition source (evaporation source)
111, 211, 311, 411: crucible
112: heating device
113: heater
114, 214, 314, 414: heating power supply
115, 215, 315, 415: opening
120: vapor deposition source moving mechanism
121: motor driving device
122: vapor deposition source lifting mechanism
130, 230, 330, 430: substrate
131, 231, 331, 431: vapor deposition target surface
140, 240, 340, 340: vapor deposition stream
141, 241, 341, 441: ejection portion
170, 270, 470: vapor deposition unit
205, 405: transfer mechanism
222, 322, 422: drive motor
243, 343, 443: vapor deposition region
250, 350, 450: mask
251, 351, 451: opening
252: mask open region
271, 371, 471: crucible supporting material
272: limiting component
273: opening
411a: vessel
411b: cover
CL: center line

1. A vapor deposition apparatus that forms a film on a substrate, comprising:
a first thickness monitor; and
a vapor deposition unit including a vapor deposition source,
the apparatus being configured to perform vapor deposition while controlling the distance between a portion of the vapor deposition source designed to eject a vaporized material and a surface of the substrate on which the vapor deposition is performed, based on a measurement result from the first thickness monitor.

2. The vapor deposition apparatus according to claim 1,
wherein the vapor deposition apparatus further comprises a vapor deposition source moving mechanism configured to move the vapor deposition source to change the height of the portion designed to eject a vaporized material.

3. The vapor deposition apparatus according to claim 1,
wherein the vapor deposition apparatus controls the distance by proportional control or PID control.

4. The vapor deposition apparatus according to claim 1,
wherein the vapor deposition source comprises a heating device,
the vapor deposition apparatus further comprises a second thickness monitor, and
the vapor deposition apparatus is configured to perform vapor deposition while controlling the output of the heating device based on a measurement result from the second thickness monitor.

5. The vapor deposition apparatus according to claim 4,
wherein the vapor deposition apparatus further comprises a vapor deposition source moving mechanism configured to move the vapor deposition source to change the height of the portion designed to eject a vaporized material,
the second thickness monitor is fixed to the vapor deposition source moving mechanism, and
the first thickness monitor is fixed to the vapor deposition unit.

6. The vapor deposition apparatus according to claim 1,
wherein the vapor deposition source comprises a heating device, and
the vapor deposition apparatus is configured to perform vapor deposition while controlling the distance and the output of the heating device based on a measurement result from the first thickness monitor.

7. The vapor deposition apparatus according to claim 1,
wherein the vapor deposition source comprises a heating device,
the vapor deposition apparatus further comprises a second thickness monitor, and
the vapor deposition apparatus is configured to perform vapor deposition while controlling the distance and the output of the heating device based on a measurement result from the first thickness monitor and controlling a proportionality coefficient in the control of the distance based on a measurement result from the second thickness monitor.

8. The vapor deposition apparatus according to claim 4,
wherein the vapor deposition apparatus controls the output by PID control.

9. The vapor deposition apparatus according to claim 1,
wherein the vapor deposition source includes a crucible provided with an opening, and
the portion designed to eject a vaporized material is the opening.

10. The vapor deposition apparatus according to claim 1,
wherein the vapor deposition apparatus further comprises a transfer mechanism configured to move at least one of the substrate and the vapor deposition source relatively to the other in a direction perpendicular to the normal direction of the substrate.

11. The vapor deposition apparatus according to claim 10,
wherein the vapor deposition unit includes the vapor deposition source and a mask, and
the transfer mechanism is configured to move at least one of the substrate and the vapor deposition unit relatively to the other.

12. The vapor deposition apparatus according to claim 10,
wherein the vapor deposition apparatus further comprises a mask, and
the transfer mechanism is configured to move at least one of the vapor deposition source and the substrate to which the mask is attached, relatively to the other.

13. The vapor deposition apparatus according to claim 1,
wherein the vapor deposition apparatus further comprises a mask and a substrate holder with a rotating mechanism designed to rotate the substrate to which the mask is attached.

14. A vapor deposition method, comprising
a vapor deposition step of forming a film on a substrate,
the vapor deposition step being performed by the vapor deposition apparatus according to claim 1.

15. A method for producing an organic electroluminescent element, comprising
a vapor deposition step of forming a film by the vapor deposition apparatus according to claim 1.
